(19) United States
(12) Patent Application Publication
(10) Pub. No.: US 2013/0320269 A1
(43) Pub. Date: Dec. 5, 2013

(54) PROCESS FOR THE PREPARATION OF SEMICONDUCTOR MATERIALS, COMPOUNDS AND THEIR USE

(71) Applicants: Nicolas Cocherel, Manchester (GB); Benjamin John Lidster, Wigan (GB); Michael L. Turner, Sale (GB)

(72) Inventors: Nicolas Cocherel, Manchester (GB); Benjamin John Lidster, Wigan (GB); Michael L. Turner, Sale (GB)

(73) Assignee: THE UNIVERSITY OF MANCHESTER, Manchester (GB)

(21) Appl. No.: 13/992,563

(22) PCT Filed: Dec. 8, 2011
(86) PCT No.: PCT/GB11/52426

§ 371 Date: Aug. 5, 2013

(30) Foreign Application Priority Data
Dec. 9, 2010 (GB) 1020882.5

(51) Int. Cl. H01L 51/00

(52) U.S. Cl. CPC H01L 51/0035; H01L 51/0072; H01L 51/0071
USPC 252/500; 548/416; 548/418; 548/417; 525/540

(57) ABSTRACT

This invention relates to a novel process for preparing compounds comprising moieties of formula (I) and polymers comprising monomers of formula (II) or (III) as defined herein. The present invention also provides novel compounds of formula (I) and novel polymers comprising monomers of formula (II) or (III) as defined herein, as well as to the use of such compounds and polymers in organic semiconductor applications. Formulae (I), (II), (III)

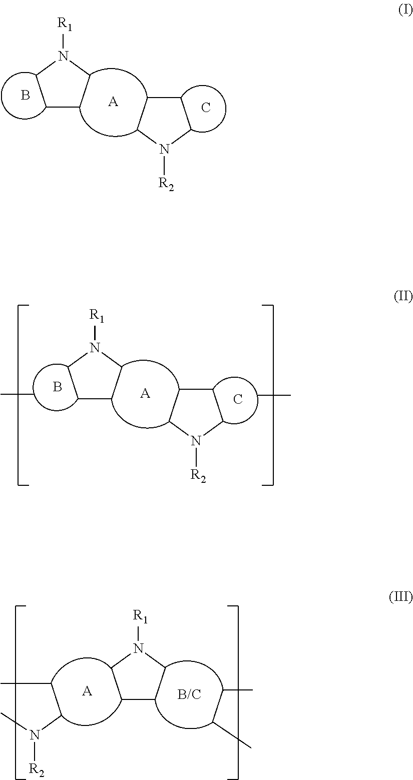

This invention relates to a novel process for preparing polycyclic π-conjugated heteroaromatic molecules. More specifically, the present invention relates to a novel process for preparing extended polycyclic π-conjugated oligomers and polymers. The present invention also relates to certain novel extended π-conjugated polycyclic heteroaromatic oligomers and polymers, as well as to the use of these oligomers and polymers as organic semiconductors.

### BACKGROUND

A new era in displays, lighting and electronics is opening with the introduction of devices fabricated using high performance organic semiconductors [see Chem. Rev. 2007, 107, Issue 4]. Particular opportunities include low power consumption, large area lighting, intelligent data tags for supply chain monitoring and ubiquitous, personalised devices that can be wearable, printable and fabricated in large numbers using lower cost facilities than conventional silicon fabrications. However, realising these devices requires high purity, well-defined organic semiconductors with robust and high performance. To deliver these requirements, efficient and scalable synthetic routes need to be developed that preferably lead to a diversity of material structures and products of the desired purity.

Transition metal catalyzed polymerisations in principle meet at least some of these requirements but in general the commercial catalysts or precursors that are employed are not necessarily optimised for the reactions required to assemble conjugated oligomers and polymers. As a consequence, high loadings of catalysts are used that can lead to significant levels of impurities in the products that are difficult to remove [Lupton et al. Phys. Rev. Lett. 2002, 89, 167401].

Carbazoles are used extensively as the active component of charge transport layers for laser printers, photocopiers and organic light emitting diodes (OLEDs) [Shirota, Y. J. Mater. Chem. 2005, 15, 75]. They are characterized by a low ionization potential (ca. 4.8-5.0 eV) and can be reversibly oxidized to generate stable radical cations that act as charge carriers [D'Andrade et al. Organic Electronics 2005, 6, 11]. Indolocarbazoles and molecular derivatives thereof have also been reported to show mobilities of over 0.1 cm²/Vs under ambient conditions when evaporated to give thin polycrystalline films [Wu et al. J. Am. Chem. Soc. 2005, 127, 614; Boudreault et al. J. Am. Chem. Soc., 2007, 129, 9125].

Indolocarbazoles are generally prepared by a Cadogan ring closure reaction or a double Fischer indole reaction. Although these synthetic routes are relatively short, the yields are disappointing (6-30%) and there is limited potential for structural diversity [Boudreault et al. Adv. Polym. Sci. 2008, 212, 99].

Kawaguchi et al. [J. Org. Chem. 2007, 72, 5119] demonstrated that palladium/phosphane catalyzed double N-arylation reactions can also be used to prepare carbazoles and indolocarbazoles.

However, there remains a need further improved processes that are suitable for synthesising a wide range of extended “carbazole-like” or “carbazole-based” polycyclic oligomers and polymers that are useful organic semiconductor materials.

There is also a need for novel extended “carbazole-like” or “carbazole-based” polycyclic conjugated heteroaromatic oligomers and polymers that are suitable for use as organic semiconductors.

It is therefore an object of the present invention to provide an improved facile process for preparing “carbazole-like” or “carbazole-based” oligomeric and polycyclic molecules that are useful as organic semiconductors.

It is a further object of the present invention to provide novel “carbazole-like” or “carbazole-based” polycyclic conjugated heteroaromatic oligomers and polymers for use as organic semiconductors.

### BRIEF SUMMARY OF THE DISCLOSURE

The present invention relates to a process for preparing extended polycyclic π-conjugated oligomers and polymers comprising “carbazole-like” or “carbazole-based” moieties. The process of the present invention essentially involves a novel oxidative cyclisation or “ring-closure” reaction to form the desired conjugated oligomers or polymers.

The oligomers and polymers of the present invention suitably comprise one or more structural moieties or motifs of the general formula I shown below:

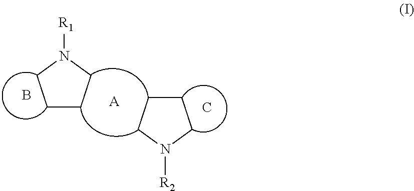

wherein:

R₁ and R₂ are substituent groups as defined herein; and
Ring A, Ring B and Ring C are π-conjugated ring systems which are optionally substituted.

In the process of the invention, compounds comprising one or more structural moieties or motifs of formula I as shown above, are prepared by forming compounds comprising one or more moieties of formula A1, A2, A3 or A4:

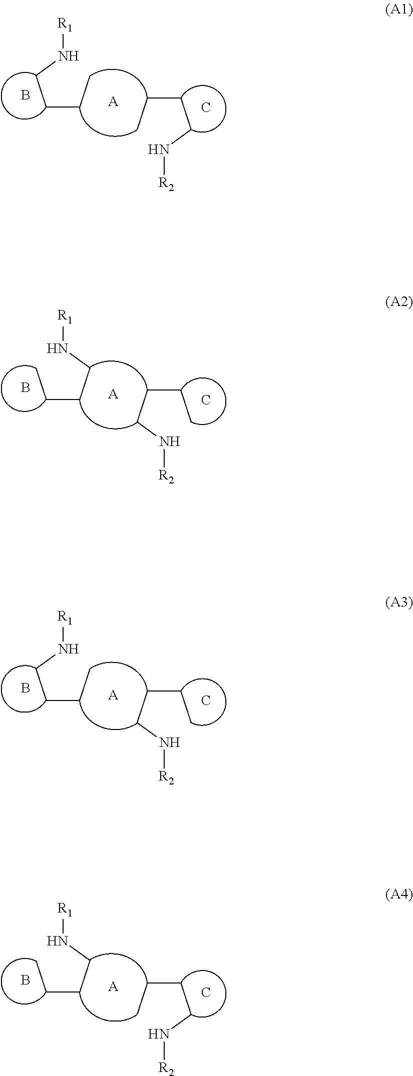

wherein Ring A, Ring B, Ring C, R₁ and R₂ are as defined above;

and reacting said compounds with an oxidant in the presence of a transition metal catalyst or a salt thereof.

Thus, in one aspect, the present invention provides a process for preparing a compound comprising one or more moieties of formula (I):

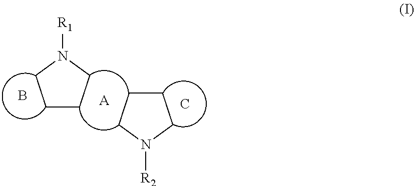

wherein:
R₁ and R₂ are substituent groups as defined herein; and
Ring A, Ring B and Ring C are π-conjugated ring systems which are optionally substituted;
   said process comprising reacting a compound of comprising one or more moieties of formula A1, A2, A3 and/or A4:

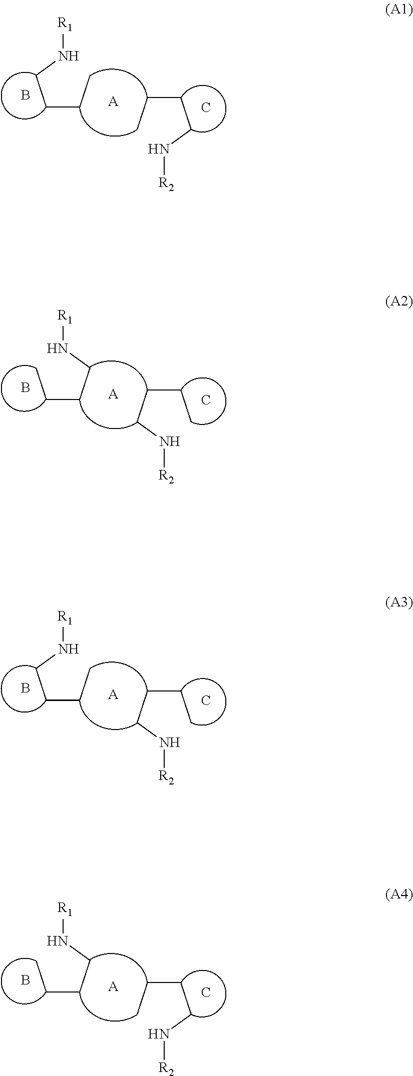

wherein Ring A, Ring B, Ring C, R₁ and R₂ are as defined above;
with an oxidant in the presence of a transition metal catalyst or a salt thereof.

In the compounds comprising moieties of formula I, the Ring B or Ring C π-conjugated ring systems are optionally bonded to, or fused to, other adjoining conjugated ring systems (which may or may not accord to the general formula I shown above).

It shall be appreciated that compounds comprising just one moiety of one of the formulae A1 to A4 above will require two oxidative cyclisation or “ring closure” reactions to occur on either side of the Ring A aromatic ring system to form a compound comprising one moiety of formula I. It will therefore be appreciated that there is a minimum of two oxidative ring closures are required to form compounds comprising a π-conjugated moiety of formula I in the process of the present invention.

However, depending on the nature of the final desired compound, there may be more than two ring closures required, for example, 3, 4, 5, 6, 7 or more ring closures may be required. In the case polymers comprising moieties of formula I, anywhere from 4 up to several thousand ring closures may be required.

In a particular embodiment of the invention, the compound is an oligomer compound of formula I as defined above.

In a further embodiment, the compound comprising one or more moieties of formula I is a polymer comprising one or more monomeric components that comprise a moiety of formula I.

In one particular embodiment, the polymer comprises monomeric component of formula II:

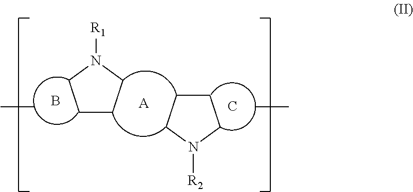

wherein Ring A, Ring B, Ring C, R₁ and R₂ are as defined herein.

In this embodiment, the pre-cursor compounds comprising moieties of the formula A1, A2, A3 and/or A4 are polymers comprising one or more monomeric components of formula B1, B2, B3 and/or B4:

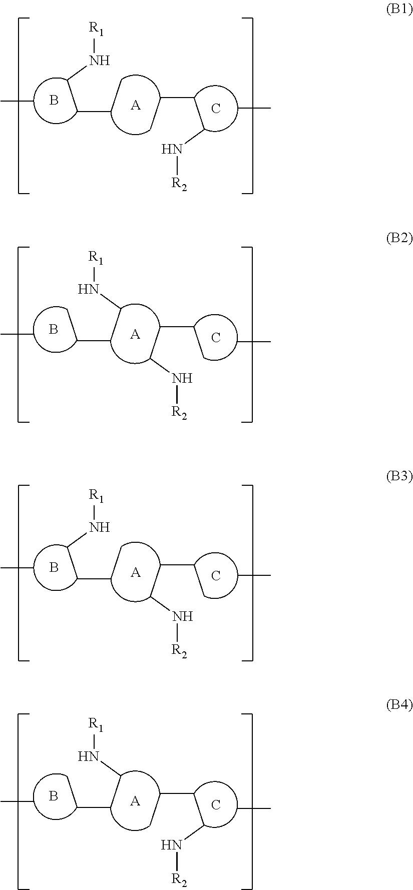

wherein Ring A, Ring B, Ring C, R₁ and R₂ are as defined above.

Thus, in one particular embodiment, the present invention provides a process for preparing a polymer comprising a monomeric component of formula II above;

said process comprising forming a polymer comprising monomeric components of formula B1, B2, B3 and/or B4;
with an oxidant in the presence of a transition metal catalyst, or a salt thereof, to form the polymer comprising a monomeric component of formula II.

The polymers formed by the above-process may be homopolymers, i.e. the polymer only comprises monomers of formula II, or co-polymers, i.e. the polymer comprises one or more additional monomeric components in addition to the monomeric component of formula II.

In a further embodiment, Ring B and Ring C are identical and the compound comprising a moiety of formula I is a ladder polymer comprising monomers of formula III:

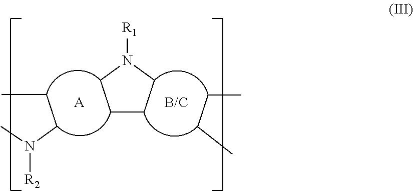

wherein R₁, R₂, Ring A and Ring B/C is a Ring B or C as defined herein.

In this embodiment, the compounds comprising moieties of formula A1 to A4 are polymers comprising monomeric components of formula C1, C2, C3 and/or C4:

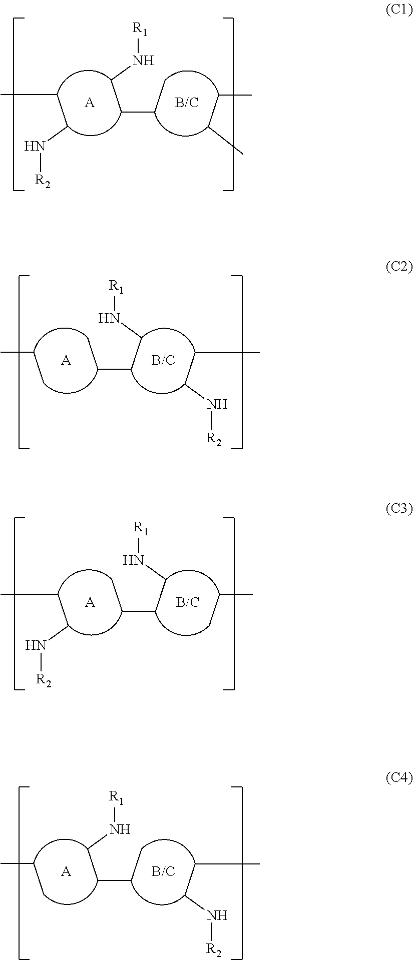

wherein Ring A, Ring B, R₁ and R₂ are as defined above.

Thus, in another aspect, the present invention provides a process for preparing a polymer comprising monomers of formula III:

said process comprising forming a polymer comprising monomeric components of formula C1, C2, C3 and/or C4 as defined herein;
and reacting said compound with an oxidant in the presence of a transition metal catalyst, or a salt thereof, to form the polymer comprising the monomers of formula III.

The polymers comprising monomers of formula III may be homopolymers, i.e. the polymer only comprises monomers of formula III, or co-polymers, i.e. the polymer comprises one or more additional monomeric components in addition to the monomeric component of the formula III.

The processes of the present invention provides a facile means of forming oligomer compounds of formula I and polymers comprising the monomeric units of formulae II and III defined herein. A single reaction step involving the use of an oxidant and a transition metal catalyst can be employed to mediate the ring closure by the direct amination of a C—H bond.

These processes provide a number of advantages compared with the conventional method to prepare extended π-conjugated “carbazole-like” or “carbazole-based” materials, including:—

a reduced number of synthetic & purification steps;

the utilisation of commercially available precursor molecules;

the provision of facile access to existing and new carbazole based or carbazole-like materials;

enabling libraries of carbazole based and/or carbazole-like materials to be readily prepared for screening evaluation; and

the use of both standard laboratory equipment & practices.

It is particularly significant that the processes of the present invention provide facile access to an abundance of novel extended polycyclic π-conjugated oligomers & polymers.

Thus, in a further aspect the present invention provides a compound of the formula (I) as defined herein, wherein Ring A, Ring B, Ring C, R₁ and R₂ are as defined herein;

with the proviso that:

(i) wherein Ring A, Ring B, and Ring C are not all phenyl;

(ii) Ring B and Ring C are not both phenyl when Ring A is a group of formula:

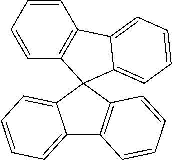 [SMILES: c1ccc2c(c1)-c1ccccc1C21c2ccccc2-c2ccccc21]

(iii) Ring A is not phenyl when both Ring B and Ring C have the formula:

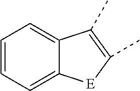

wherein E is as defined herein.

In a further aspect, the present invention provides a polymer comprising monomeric components of formula II, wherein Ring A, Ring B, Ring C, R₁ and R₂ are as defined herein, subject to the proviso that Rings A, B, and C cannot all be phenyl.

In another aspect, the present invention provides a polymer comprising monomeric components of formula III wherein Ring A, Ring B, R₁ and R₂ are as defined herein.

In another aspect, the present invention relates to the use of oligomers of formula I as defined herein and/or polymers comprising monomeric components of formula II or formula III as defined herein, or mixtures thereof, as materials for organic semiconductor applications.

In a further aspect, the present invention provides novel intermediates compounds of the formulae A1, A2, A3 or A4 as defined herein, which are useful intermediates for the preparation of oligomers of formula I as defined herein.

In yet another aspect, the present invention provides polymers comprising monomeric units of the formulae B1, B2, B3 or B4 as defined herein, which are useful intermediates for the preparation of polymers comprising monomeric components of formula II as defined herein.

In yet another aspect, the present invention provides polymers comprising monomeric units of the formula C1, C2, C3 or C4 as defined herein, which are useful intermediates for the preparation of polymers comprising monomeric components of formula III as defined herein.

In another aspect the present invention relates to a formulation comprising:
one or more oligomers of formula I as defined herein, or polymers comprising monomeric components of formula II or formula III as defined herein;
one or more solvents;
and optionally one or more binders, preferably organic binders, or precursors thereof.

In another aspect the present invention relates to a formulation comprising:
one or more oligomers of formula I as defined herein, or polymers comprising monomeric components of formula II or formula III as defined herein;
one or more binders, preferably organic binders, or precursors thereof; and optionally one or more solvents.

In another aspect, the present invention provides an organic semiconductor layer comprising:
one or more oligomers of formula I as defined herein, or polymers comprising monomeric components of formula II or formula III as defined herein, or a formulation as defined herein.

The present invention further relates to a process for preparing an organic semiconductor layer as defined herein, comprising the steps of:
(i) depositing on a substrate a liquid layer of a formulation as defined herein;
(ii) forming from the liquid layer a solid layer which forms the organic semiconductor layer; and
(iii) optionally removing the layer from the substrate.

In a further aspect, the present invention relates to the use of:
oligomers of formula I as defined herein or polymers comprising monomeric components of formula II or formula III as defined herein, or mixtures thereof;
or a formulation as defined herein;
or an organic semiconductor layer as defined herein;
in an electronic, optical or electro-optical component or device.

In a further aspect, the present invention relates to an electronic, optical or electro-optical component or device comprising oligomers of formula I as defined herein, or polymers comprising monomeric components of formula II or formula III as defined herein, or mixtures thereof, or a formulation as defined herein, or an organic semiconductor layer as defined herein.

The electronic, optical or electro-optical component or device may include, but is not limited to, an organic field effect transistor (OFET), a thin film transistor (TFT), a component of integrated circuitry (IC), a radio frequency identification (RFID) tags, an organic light emitting diodes (OLED), an electroluminescence display, a flat panel display, a backlight, a photodetector, a sensor, a logic circuit, a memory element, a capacitor, a photovoltaic (PV) cell, a photoconductor, and an electrophotographic element.

### DETAILED DESCRIPTION

### Definitions

Unless stated otherwise, the following terms have the following meanings in this specification:

The term “alkyl” includes both straight and branched chain alkyl groups. References to individual alkyl groups such as “propyl” are specific for the straight chain version only and references to individual branched chain alkyl groups such as “isopropyl” are specific for the branched chain version only. For example, “(1-20C)alkyl” includes (1-4C)alkyl, (1-3C)alkyl, propyl, isopropyl and t-butyl. A similar convention applies to other radicals mentioned herein.

The terms “alkenyl” and “alkynyl” include both straight and branched chain alkenyl and alkynyl groups.

The term “halo” refers to fluoro, chloro, bromo and iodo.

The term “fluoroalkyl” means an alkyl group as defined herein which is substituted with one or more fluoro atoms, e.g. —CF₃, or —CH₂CF₃ and the like. Suitably, a fluoroalkyl group is a trifluoro-substituted alkyl group.

The term “π-conjugated ring system” refers to conjugated aromatic ring system that may comprise one, two or three rings joined to form a π-conjugated ring system. In one embodiment, then-conjugated ring system may be an aryl and/or heteroaromatic ring system comprising one, two or three fused aromatic or heteroaromatic rings. In another embodiment, the ring system may comprise a conjugated system comprising a central non-aromatic ring fused between two aromatic or heteroaromatic rings, provided the ring system overall remains conjugated. An example of such a ring system is:

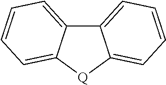

wherein Q is as defined herein.

The term “aryl” is used herein to denote phenyl, naphthalene or anthracene ring. In an embodiment, an “aryl” is phenyl or naphthalene, and particularly is phenyl.

The term “heteroaryl” or “heteroaromatic” means an aromatic mono-, bi-, or tri-cyclic ring incorporating one or more (for example 1-4, particularly 1, 2 or 3) heteroatoms selected from N, O, S, Si or Se. Examples of heteroaryl groups are monocyclic, bicyclic and tricyclic groups containing from five to eighteen ring members. The heteroaryl group can be, for example, a 5- or 6-membered monocyclic ring, a 8-, 9- or 10-membered bicyclic ring or a 15-, 16-, 17- or 18-membered tricyclic ring. Suitably each ring in a bicyclic or tricyclic ring system comprises five or six ring atoms.

The term “heterocyclyl”, “heterocyclic” or “heterocycle” means a non-aromatic saturated or partially saturated monocyclic, fused, bridged, or spiro bicyclic heterocyclic ring system(s). The term heterocyclyl includes both monovalent species and divalent species. Monocyclic heterocyclic rings contain from about 3 to 12 (suitably from 3 to 7) ring atoms, with from 1 to 5 (suitably 1, 2 or 3) heteroatoms selected from nitrogen, oxygen or sulfur in the ring. Bicyclic heterocycles contain from 7 to 17 member atoms, suitably 7 to 12 member atoms, in the ring. Bicyclic heterocycles contain from about 7 to about 17 ring atoms, suitably from 7 to 12 ring atoms. Bicyclic heterocyclic(s) rings may be fused, Spiro, or bridged ring systems. As the skilled person would appreciate, any heterocycle may be linked to another group via any suitable atom, such as via a carbon or nitrogen atom.

The term “cross-linking moiety” is used herein to refer to any functional cross-linking group known in the art that can be used to link one polymer chain to another, whether by way of covalent or ionic bonds. Examples of such groups include thiols, alkynes, azides, amines and carboxylic acids.

The term “polymerisable group” is used herein to refer to any functional group that can be polymerized. Examples of such groups include oxirane, oxetane, acrylate, methacrylate, styrene or a heteroaryl group (especially thiophene) which is optionally substituted by (1-20C)alkyl.

### Processes for Forming Compounds Comprising Moieties of Formula I

As stated above, in one aspect the present invention provides processes for preparing compounds comprising moieties of formula I. Any π-conjugated oligomer or polymer compounds that comprises a moiety according to formula I as defined herein can be prepared by the process of the present invention. By way of example, a compound of the formula:

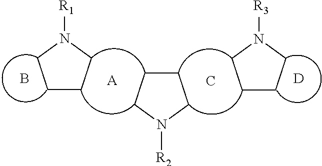

in which Ring A, Ring B, Ring C, R₁ and R₂ are as defined herein, and R₃ is a substituent group equivalent to R₁ or R₂ and Ring D is conjugated ring system equivalent to Rings A, B or C; is encompassed by the process of the present invention and could be prepared, for example, by the reaction of a compound of the formula:

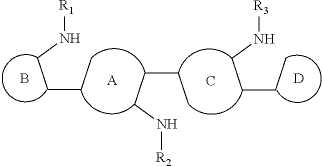

with an oxidant in the presence of a transition metal catalyst, or a salt thereof.

In an embodiment, the compounds are oligomers and, in an alternative embodiment, the compounds are polymers.

In the compounds comprising moieties of formula I, R₁ and R₂ may be any suitable substituent group known in the art. For example, R₁ and R₂ may be hydrocarbyl substituent groups optionally comprising 1 to 30 carbon atoms and optionally comprising one or more heteroatoms (e.g. N, O, S, Si, or P).

In an embodiment, R₁ and R₂ are each independently selected from (1-20C)alkyl, (2-20C)alkenyl, (2-20C)alkynyl, (2-20C)alkanoyl, (1-20C)alkyl-SO₂—; or a group

-Z¹-Q¹
wherein Z¹ is a direct bond, —CO— or —SO₂—; and
Q¹ is selected from aryl, heteroaryl, heterocyclyl, (3-8C)cycloalkyl, aryl-(1-10C)alkyl, heteroaryl-(1-10C)alkyl, heterocyclyl-(1-10C)alkyl, or (3-8C)cycloalkyl-(1-10C)alkyl; and wherein Q¹ is optionally substituted with one or more halo, nitro, cyano, hydroxy, (1-20C)alkyl, (2-20C)alkenyl, (2-20C)alkynyl or (2-20C)alkanoyl groups;
and wherein a R₁ or R₂ substituent group is optionally further substituted by one or more substituents Ra as defined herein.

In an embodiment, each R^{a} group present is independently selected from halo, nitro, cyano, hydroxy, (1-20C)alkyl, (1-10C)fluoroalkyl (1-10C)fluoroalkoxy amino, carboxy, carbamoyl, mercapto, sulfonylamino, (1-10C)alkoxy, (2-10C)alkanoyl, (1-10C)alkanoyloxy, a cross-linking moiety or a polymerisable group.

Ring A, Ring B and Ring C are π-conjugated ring systems that are optionally substituted by one or more suitable substituent groups. Any suitable substituent group or groups may be present on Ring A, Ring B or Ring C. In a particular embodiment, Ring A, Ring B and Ring C are optionally substituted by one or more R^{b} groups as defined herein.

In an embodiment, each R^{b} group present is independently selected from halo, nitro, cyano, hydroxy, (1-20C)alkyl, (1-10C)fluoroalkyl, (1-10C)fluoroalkoxy, amino, carboxy, carbamoyl, mercapto, sulfonylamino, (1-10C)alkoxy, (2-10C)alkanoyl, (1-10C)alkanoyloxy, a cross-linking moiety or a polymerisable group; aryl, heteroaryl, heterocyclyl, or (3-8C)cycloalkyl, aryl-(1-10C)alkyl, heteroaryl-(1-10C)alkyl, heterocyclyl-(1-10C)alkyl, or (3-8C)cycloalkyl-(1-10C)alkyl; and wherein any aryl, heteroaryl, heterocyclyl, or (3-8C)cycloalkyl moiety within a R^{b} substituent groups is optionally substituted with one or more halo, nitro, cyano, hydroxy, (1-20C)alkyl, (2-20C)alkenyl, (2-20C)alkynyl or (2-20C)alkanoyl groups.

In a particular embodiment, the compound comprising a moiety of formula I only comprises that moiety, i.e. the compound is a compound of formula I.

In another embodiment, the compound comprising a moiety of formula I is a polymer comprising monomers of formula II or formula III as defined herein.

Particular compounds comprising moieties of formula I include, for example, those compounds or monomers described herein in which, unless otherwise stated, each of R₁, R₂, R^{a}, R^{b}, Ring A, Ring B or Ring C has any of the meanings defined hereinbefore or in any of paragraphs (1) to (30) hereinafter:—
(1) R₁ and R₂ are each independently selected from (1-20C)alkyl, (2-20C)alkenyl, (2-20C)alkynyl, (2-20C)alkanoyl, (1-20C)alkyl-SO₂—; or a group

-Z¹-Q¹
wherein Z¹ is a direct bond, —CO— or —SO₂—; and
Q¹ is selected from aryl, heteroaryl, heterocyclyl, (3-8C)cycloalkyl, aryl-(1-10C)alkyl, heteroaryl-(1-10C)alkyl, heterocyclyl-(1-10C)alkyl, or (3-8C)cycloalkyl-(1-10C)alkyl; and wherein Q¹ is optionally substituted with one or more (1-20C)alkyl, (2-20C)alkenyl, (2-20C)alkynyl or (2-20C)alkanoyl groups;
and wherein a R₁ or R₂ substituent group is optionally further substituted by one or more substituents R^{a} as defined herein;
(2) R₁ and R₂ are each independently selected from (1-20C)alkyl, (2-20C)alkenyl, (2-20C)alkynyl, (2-20C)alkanoyl, (1-20C)alkyl-SO₂—; or a group

-Z¹-Q¹
wherein Z¹ is a direct bond, —CO— or —SO₂—; and
Q¹ is selected from aryl, heteroaryl, heterocyclyl, or (3-8C)cycloalkyl; and
wherein Q¹ is optionally substituted with one or more (1-20C)alkyl, (2-20C)alkenyl, (2-20C)alkynyl or (2-20C)alkanoyl groups;
and wherein a R₁ or R₂ substituent group is optionally substituted by one or more substituents Ra as defined herein;
(3) R₁ and R₂ are each independently selected from (1-20C)alkyl, (2-20C)alkenyl, (2-20C)alkynyl, (2-20C)alkanoyl, (1-20C)alkyl-SO₂—; or a group

-Z¹-Q¹
wherein Z¹ is a direct bond, —CO— or —SO₂—; and
Q¹ is selected from aryl or heteroaryl; and wherein Q¹ is optionally substituted with a (1-20C)alkyl, (2-20C)alkenyl, (2-20C)alkynyl or (2-20C)alkanoyl group;
and wherein a R₁ or R₂ substituent group is optionally substituted by one or more substituents Ra as defined herein;
(4) R₁ and R₂ are each independently selected from (1-20C)alkyl, (2-20C)alkenyl, (2-20C)alkynyl, (2-20C)alkanoyl, (1-20C)alkyl-SO₂—; or a group

-Z¹-Q¹
wherein Z¹ is a direct bond, —SO₂— or —CO—; and
Q¹ is aryl, which is optionally substituted with one or more (1-20C)alkyl, (2-20C)alkenyl, (2-20C)alkynyl or (2-20C)alkanoyl groups;
and wherein a R₁ or R₂ substituent group is optionally substituted by one or more substituents Ra as defined herein;
(5) R₁ and R₂ are each independently selected from (1-20C)alkyl, (2-20C)alkenyl, (2-20C)alkynyl, (2-20C)alkanoyl, (1-20C)alkyl-SO₂—; or a group

-Z¹-Q¹
wherein Z¹ is a direct bond, —SO₂— or —CO—; and
Q¹ is phenyl, which is optionally substituted by (1-20C)alkyl, (2-20C)alkenyl, (2-20C)alkynyl or (2-20C)alkanoyl groups in the para position;
and wherein a R₁ or R₂ substituent group is optionally substituted by one or more substituents Ra as defined herein;
(6) R₁ and R₂ are each independently selected from (6-16C)alkyl, (6-16C)alkenyl, (6-16C)alkynyl, (6-16C)alkanoyl, (6-16C)alkyl-SO₂—; or a group

-Z¹-Q¹
wherein Z¹ is a direct bond, —SO₂— or —CO—; and
Q¹ is phenyl, which is optionally substituted by (1-16C)alkyl, (2-16C)alkenyl, (2-16C)alkynyl or (2-16C)alkanoyl;
and wherein a R₁ or R₂ substituent group is optionally substituted by one or more substituents Ra as defined herein;
(7) R₁ and R₂ are each independently selected from (1-20C)alkyl, (2-20C)alkanoyl, (1-20C)alkyl-SO₂—, or a group

-Z¹-Q¹
wherein Z¹ is a direct bond, —SO₂— or —CO—; and
Q¹ is phenyl optionally substituted by (1-20C)alkyl;
(8) R₁ and R₂ are each (6-16C)alkyl, (6-16C)alkanoyl, (6-16C)alkyl-SO₂—, or a group

-Z¹-Q¹
wherein Z¹ is a direct bond, —SO₂— or —CO—; and
Q¹ is phenyl, which is substituted by (1-20C)alkyl;
(9) each R^{a} group present is independently selected from halo, nitro, cyano, hydroxy, (1-10C)fluoroalkyl (e.g. (1-10C)trifluoroalkyl), (1-10C)fluoroalkoxy (e.g. (1-10C)trifluoroalkoxy), amino, carboxy, carbamoyl, mercapto, sulfonylamino, (1-10C)alkoxy, (2-10C)alkanoyl, (1-10C)alkanoyloxy, a cross-linking moiety or a polymerisable group;
(10) each R^{a} group present is independently selected from halo, nitro, cyano, hydroxy, (1-10C)trifluoroalkyl, (1-10C)trifluoroalkoxy, amino, carboxy, carbamoyl, mercapto, sulfonylamino, (1-10C)alkoxy, (2-10C)alkanoyl, (1-10C)alkanoyloxy, a cross-linking moiety or a polymerisable group;
(11) Ring A is a conjugated aromatic group containing one, two or three rings, which are optionally substituted by one or more substituent groups R^{b};
(12) Ring A is a conjugated aromatic group selected from:
   a single phenyl ring;
   a single 5- or 6-membered heteroaromatic ring comprising 0, 1 or 2 heteroatoms;
   a bicyclic ring comprising two fused 5- or 6-membered aromatic rings and 0, 1, 2 or 3 heteroatoms;
   a tri-cyclic ring system comprising three fused 5- or 6-membered aromatic rings and 0, 1, 2, 3 or 4 heteroatoms; or
   a tri-cyclic ring system comprising three fused 5- or 6-membered rings and 0, 1, 2 or 3 heteroatoms, wherein the central ring is non-aromatic and is fused in between two aromatic rings selected from phenyl and/or a 5- or 6-membered heteroaromatic ring comprising 1 or 2 heteroatoms;
   and wherein any of the above is optionally substituted by one or more substituent groups R^{b}.
(13) Ring A is selected from a conjugated aromatic group of the formula:

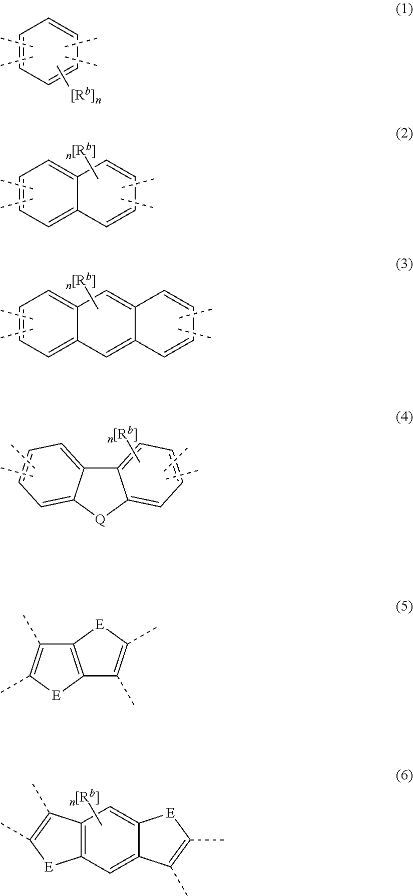

wherein:
the hashed bonds in formulae (1), (2), (3), (4) or (6) indicate the ring in which two adjacent ring atoms form the point of fusion to the adjacent pyrrole ring of formula I, II or III,
the hashed bonds in formula (5) indicate that point of attachment to the adjacent pyrrole ring;
n is 0, 1 or 2; and R^{b}, when present, is as defined herein and may positioned at any available position on conjugated aromatic groups of formulae (1), (2), (3), (4) or (6);
Q is selected from O, S, SO₂, Se, SiR₂R₃, C═NR₄, C═O, C═S, C═CR₅R₆ or CR₇R₈;
R₂ and R₃ are independently selected from hydrogen, (1-20C)alkyl, (2-20C)alkenyl, (2-20C)alkynyl or aryl optionally substituted with (1-20C)alkyl, or R₂ and R₃ are linked to form an optionally fused ring;
R₄, R₅ and R₆ are independently selected from hydrogen, (1-20C)alkyl, (2-20C)alkenyl, (2-20C)alkynyl, or aryl optionally substituted with (1-20C)alkyl;
R₇ and R₈ are independently selected from hydrogen, (1-20C)alkyl, (2-20C)alkenyl, (2-20C)alkynyl or aryl optionally substituted with (1-20C)alkyl; or R₇ and R₈ are linked such that, together with the carbon atom to which they are attached, they form a 5 or 6-membered ring, which is optionally fused with one or two further aryl or heteroaryl rings and is optionally substituted by one or more R^{b}; and
E is selected from S, Se, O or NR₉ (wherein R₉ is hydrogen or (1-20C)alkyl).
(14) Ring A is selected from a conjugated aromatic group of the formula (1), (2), (3), (4), (5) or (6) shown in paragraph (13) above
   wherein:
   the hashed bonds in formulae (1), (2), (3), (4) or (6) indicate the ring in which two adjacent ring atoms form the point of fusion to the adjacent pyrrole ring of formula I, II or III,
   the hashed bonds in formula (5) indicate that point of attachment to the adjacent pyrrole ring;
   n is 0 or 1 or 2; and R^{b}, when present, is as defined herein and may positioned at any available position on conjugated aromatic groups of formulae (1), (2), (3), (4) or (6);
   Q is selected from O, S, SO₂, Se, SiR₂R₃, C═NR₄, C═O, C═S, C═CR₅R₆ or CR₇R₈;
   R₂ and R₃ are independently selected from hydrogen, (1-20C)alkyl or aryl optionally substituted with (1-20C)alkyl;
   R₄, R₅ and R₆ are selected from hydrogen or (1-20C)alkyl;
   R₇ and R₈ are independently selected from hydrogen, (1-20C)alkyl or aryl optionally substituted with (1-20C)alkyl; or R₇ and R₈ are linked such that, together with the carbon atom to which they are attached, they form a 5 or 6-membered ring, which is optionally fused with one or two further aryl or heteroaryl rings and is optionally substituted by one or more R^{b}; and
   E is selected from S, Se, O or NR₉ (wherein R₉ is hydrogen or (1-20C)alkyl).
(15) Ring A is selected from a conjugated aromatic group of the formula:

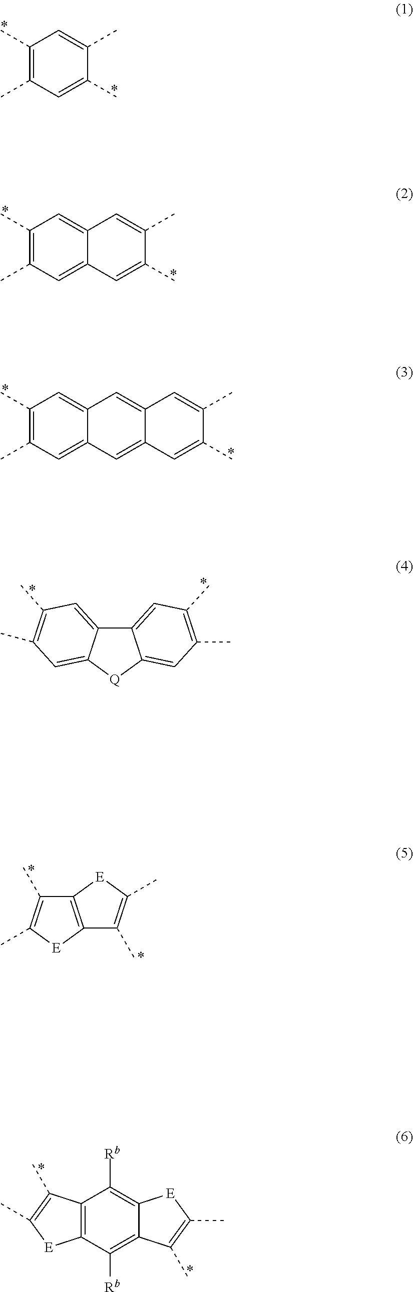

wherein:
the hashed bonds indicate that point of attachment to the adjacent pyrrole ring and * indicates the point of attachment to the N—R₁ groups of formulae I, II or III;
R^{b} has any one of definitions set out herein;
Q is selected from O, S, SO₂, Se, SiR₂R₃, C═NR₄, C═O, C═S, C═CR₅R₆, or CR₇R₈;
R₂ and R₃ are independently selected from hydrogen, (1-20C)alkyl, (2-20C)alkenyl, (2-20C)alkynyl or aryl, or R₂ and R₃ are linked to form an optionally fused ring;
R₄, R₅, and R₆ are independently selected from hydrogen, (1-20C)alkyl, (2-20C)alkenyl, or (2-20C)alkynyl;
R₇ and R₈ are independently selected from hydrogen, (1-20C)alkyl, (2-20C)alkenyl, (2-20C)alkynyl or aryl; or R₇ and R₈ are linked such that, together with the carbon atom to which they are attached, they form a 5 or 6-membered ring, which is optionally fused with one or two further aryl or heteroaryl rings and is optionally substituted by one or more R^{b}; and
E is selected from S, Se, O or NR₉ (wherein R₉ is hydrogen or (1-20C)alkyl).
(16) Ring A is selected from a conjugated aromatic group of the formula:

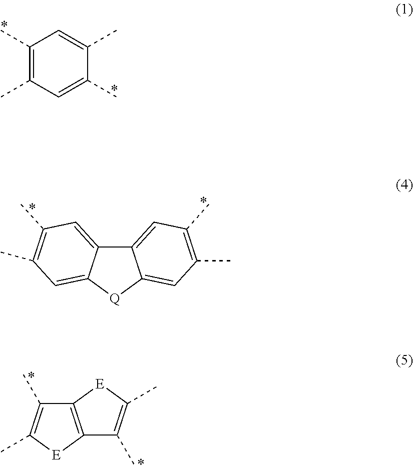

where * indicates the point of attachment to the N—R₁ groups of formulae I, II or III;
Q is selected from O, S, SO₂, Se, SiR₂R₃, C═NR₄, C═O, C═S, C═CR₅R₆, or CR₇R₈; R₂, R₃, R₄, R₅, R₆, R₇ and R₈ are independently selected from hydrogen or (1-20C)alkyl;
or R₇ and R₈ are linked such that, together with the carbon atom to which they are attached, they form a 5 or 6-membered ring, which is optionally fused with one or two aryl or heteroaryl rings and is optionally substituted by a group R^{b}; and
E is selected from S, Se, NR₉ (wherein R₉ is hydrogen or (1-20C)alkyl) or O.
(17) Ring A is selected from a conjugated aromatic group of the formula:

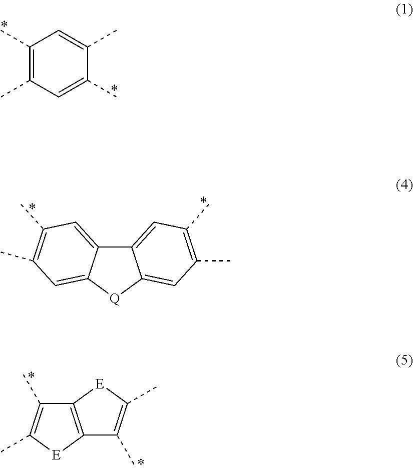

where * indicates the point of attachment to the N—R₁ groups of formulae I, II or III;
Q is selected from O, S, SO₂, Se, SiR₂R₃, C═NR₄, C═O, C═S, C═CR₅R₆, or CR₇R₈;
R₂, R₃, R₄, R₅, R₈, R₇ and R₃ are independently selected from hydrogen or (6-16C)alkyl;
or R₇ and R₈ are linked such that, together with the carbon atom to which they are attached, they form a 5 or 6-membered ring, which is optionally substituted by halo, CF₃, or (6-16C)alkyl; and/or the 5 or 6-membered ring is optionally fused with one or two aryl or heteroaryl rings which are optionally substituted with halo, CF₃, or (6-16C)alkyl; and
E is selected from S, Se, NR₉ (wherein R₉ is hydrogen or (1-20C)alkyl) or O.
(18) Ring A is:

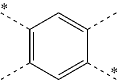

where * indicates the point of attachment to the N—R₁ groups of formulae I, II or Ill;
(19) Ring B and Ring C are each independently a conjugated aromatic group containing one, two or three rings, which are optionally substituted by one or more substituent groups R^{b};
(20) Ring B and Ring C are conjugated aromatic groups selected from:
   a single phenyl ring;
   a single 5- or 6-membered heteroaromatic ring comprising 0, 1 or 2 heteroatoms;
   a bicyclic ring comprising two fused 5- or 6-membered aromatic rings and 0, 1, 2 or 3 heteroatoms;
   a tri-cyclic ring system comprising three fused 5- or 6-membered aromatic rings and 0, 1, 2, 3 or 4 heteroatoms; or
   a tri-cyclic ring system comprising three fused 5- or 6-membered rings and 0, 1, 2 or 3 heteroatoms, wherein the central ring is non-aromatic and is fused in between two aromatic rings selected from phenyl and/or a 5- or 6-membered heteroaromatic ring comprising 1 or 2 heteroatoms;
   and wherein any of the above is optionally substituted by one or more substituent groups R^{b}.
(21) Ring B and Ring C are each independently selected from a conjugated aromatic group selected from phenyl, naphthyl, a monocyclic 5- or 6-membered heteroaryl ring or a bi- or tri-cyclic heteroaryl ring, and wherein Ring B is optionally substituted with one or more R^{b};
(22) Ring B and Ring C are conjugated aromatic group selected from:

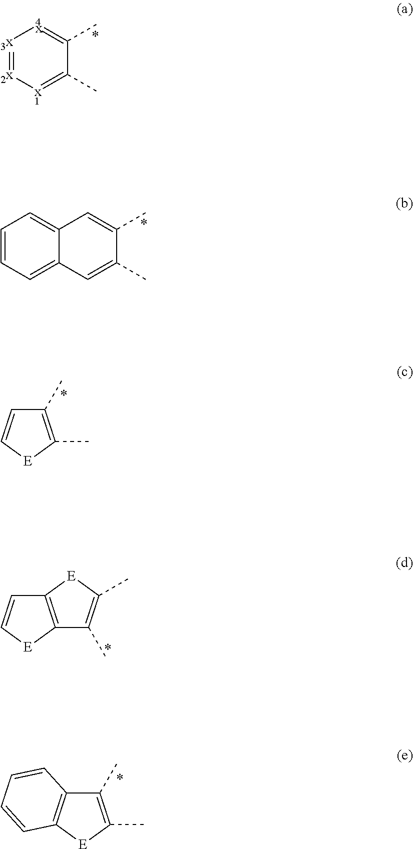

where * indicates the point of attachment to the N—R₁ groups of formulae I, II or III;
E is selected from S, Se, NR₉ (wherein R₉ is hydrogen or (1-20C)alkyl) or O;
x₁, x₂, x₃ or x₄ are all C—H or one or two of x₁, x₂, x₃ or x₄ are selected from N and the others are C—H;
and each of the ring systems depicted above is optionally substituted by 1 or 2 R^{b}.
(23) Ring B is a conjugated aromatic group selected from:

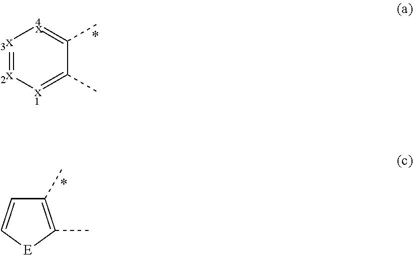

where * indicates the point of attachment to the N—R₁ groups of formulae I, II or III;
E is selected from S, Se, NR₉ (wherein R₉ is hydrogen or (1-20C)alkyl) or O; and
x₁, x₂, x₃ or x₄ are all C—H or one of x₁, x₂, x₃ or x₄ are selected from N and the others are C—H;
and each of the ring systems depicted above is optionally substituted by 1 or 2 R^{b}.
(24) Ring B is a conjugated aromatic group selected from:

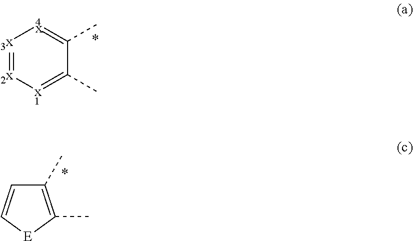

where * indicates the point of attachment to the N—R₁ groups of formulae I, II or III;
E is selected from S, Se, NR₉ (wherein R₉ is hydrogen or (1-20C)alkyl) or O; and
x₁, x₂, x₃ or x₄ are all C—H;
(25) each R^{b} group present is independently selected from halo, hydroxy, (1-20C)alkyl, (1-10C)fluoroalkyl, (1-10C)fluoroalkoxy, amino, (1-10C)alkoxy, (2-10C)alkanoyl, (1-10C)alkanoyloxy , a cross-linking moiety or a polymerisable group, aryl, heteroaryl, heterocyclyl, or (3-8C)cycloalkyl, aryl-(1-10C)alkyl, heteroaryl-(1-10C)alkyl, heterocyclyl-(1-10C)alkyl, or (3-8C)cycloalkyl-(1-10C)alkyl; and wherein any aryl, heteroaryl, heterocyclyl, or (3-8C)cycloalkyl moiety within a R^{b} substituent groups is optionally substituted with one or more halo, nitro, cyano, hydroxy, (1-20C)alkyl, (2-20C)alkenyl, (2-20C)alkynyl or (2-20C)alkanoyl groups;
(26) each R^{b} group present is independently selected from halo, (1-20C)alkyl, (1-10C)fluoroalkyl, (1-10C)fluoroalkoxy, (1-10C)alkoxy, (2-10C)alkanoyl, aryl, heteroaryl, aryl-(1-10C)alkyl, or heteroaryl-(1-10C)alkyl; and wherein any aryl or heteroaryl moiety within a R^{b} substituent groups is optionally substituted with one or more halo, (1-20C)alkyl or (2-20C)alkanoyl groups;
(27) each R^{b} group present is independently selected from halo, (1-20C)alkyl, (2-10C)alkanoyl, aryl, or aryl-(1-10C)alkyl; and wherein any aryl within a R^{b} substituent groups is optionally substituted with one or more halo or (1-20C)alkyl groups;
(28) each R^{b} group present is independently selected from (1-20C)alkyl, aryl optionally substituted with one or more (1-20C)alkyl groups;
(29) R^{b} is selected from halo, nitro, cyano, hydroxy, (1-10C)fluoroalkyl (e.g. (1-10C)trifluoroalkyl), (1-10C)fluoroalkoxy (e.g. (1-10C)trifluoroalkoxy), amino, carboxy, carbamoyl, mercapto, sulfonylamino, (1-10C)alkoxy, (2-10C)alkanoyl, 10C)alkanoyloxy , a cross-linking moiety or a polymerisable group;
(30) R^{b} is selected from halo, nitro, cyano, hydroxy, (1-10C)trifluoroalkyl, (1-10C)trifluoroalkoxy, amino, carboxy, carbamoyl, mercapto, sulfonylamino, (1-10C)alkoxy, (2-10C)alkanoyl, (1-10C)alkanoyloxy , a cross-linking moiety or a polymerisable group.

Suitably, Ring B and Ring C in formula I are the same.

Suitably, R₁ and R₂ in formula I are the same.

Particular oligomer compounds of structural formula I defined herein are selected from any one of the following:
5,11-Didodecyl-5,11-dihydroindolo[3,2-b]carbazole;
5,8-Didodecyl-14,14-diethyl-8,14-dihydro-5H-cyclopenta[1,2-b:5,4-b′]dicarbazole;
5,11-bis(4-octylphenyl)-5,11-dihydroindolo[3,2-b]carbazole;
14,14-diethyl-5,8-bis(4-octylphenyl)-8,14-dihydro-5H-cyclopenta[1,2-b:5,4-b]dicarbazole;
5,8-bis(4-octylphenyl)-5,8-dihydrothieno[3,2-b:4,5-b′]dicarbazole;
5,8-didodecyl-5,8-dihydrothieno[3,2-b:4,5-b′]dicarbazole;
5,8-didodecyl-5H-cyclopenta[1,2-b:5,4-b′]dicarbazol-14(8H)-one;
bis(dodecyl)-diindolo-thieno[3,2-b]thiophene;
bis(dodecylsulfonyl)-diindolo-thieno[3,2-b]thiophene;
5,11-bis(dodecylsulfonyl)-5,11-dihydroindolo[3,2-b]carbazole;
5,11-ditosyl-5,11-dihydroindolo[3,2-b]carbazole;
1,1′-(indolo[3,2-b]carbazole-5,11-diyl)bis(decan-1-one);
5,12-didodecyl-5,12-dihydrocarbazolo[3,2-b]carbazole;
5,12-bis(dodecylsulfonyl)-5,12-dihydrocarbazolo[3,2-b]carbazole; or
5,13-bis(4-decylphenyl)-7,15-diphenyl-5,13-dihydrobenzo[1,2-b:4,5-b′]dicarbazole.

Specific polymers comprising monomers of formula II defined herein include: Poly(dodecylindolocarbazole); or Poly(dodecylcarbazole-didodecylindolocarbazole-paraphenylene).

In the description of the synthetic methods described herein and in any referenced synthetic methods that are used to prepare the starting materials, it is to be understood that all proposed reaction conditions, including choice of solvent, reaction atmosphere, reaction temperature, duration of the experiment and workup procedures, can be selected by a person skilled in the art.

It will also be understood by one skilled in the art of organic synthesis that the functionality present on various portions of the molecule must be compatible with the reagents and reaction conditions utilised.

It will be appreciated that during the synthesis of the compounds of the invention in the processes defined herein, or during the synthesis of certain starting materials, it may be desirable to protect certain substituent groups to prevent their undesired reaction. The skilled chemist will appreciate when such protection is required, and how such protecting groups may be put in place, and later removed.

For examples of protecting groups see one of the many general texts on the subject, for example, ‘Protective Groups in Organic Synthesis’ by Theodora Green (publisher: John Wiley & Sons). Protecting groups may be removed by any convenient method described in the literature or known to the skilled chemist as appropriate for the removal of the protecting group in question, such methods being chosen so as to effect removal of the protecting group with the minimum disturbance of groups elsewhere in the molecule.

### Preparation of Compounds Comprising Moieties of Formula I

As stated above, the compounds comprising one or more moieties of formula I as defined herein are prepared by forming compounds comprising one or more moieties of formula A1, A2, A3 and/or A4:

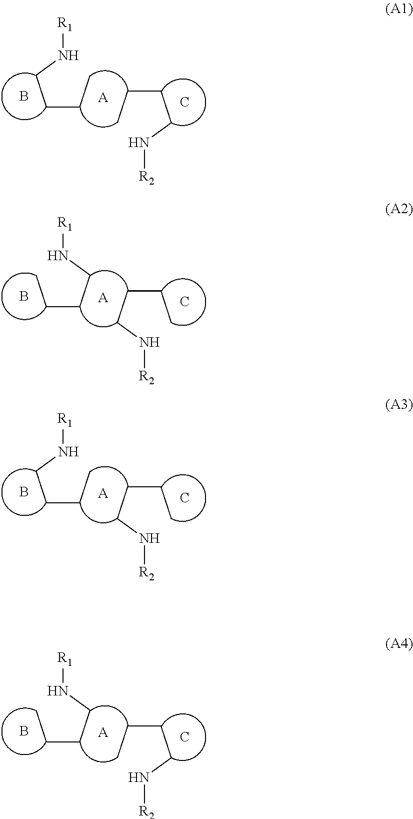

wherein Ring A, Ring B, Ring C, R₁ and R₂ are as defined above;
and reacting said compounds with an oxidant in the presence of a transition metal catalyst or a salt thereof.

Any suitable oxidant may be used in the processes. In an embodiment, the oxidant is selected from O₂, phenyliodium diacetate (PIDA), or DMSO. In a particular embodiment, the oxidant is PIDA.

Any suitable transition metal catalyst may be used in the processes of the present invention. In an embodiment, the transition metal catalyst is selected from palladium, nickel, platinum, iron, ruthenium, gold, iridium, silver, cobalt, rhodium, mercury, or copper, or a salt thereof. In an embodiment, the catalyst is palladium diacetate.

Typically, the reaction will be carried out at a temperature within the range of 0 to 250° C. Suitably, the reaction is carried out at room temperature (typically 20 to 25° C.).

A person skilled in the art will appreciate that the reaction time will vary depending on the reaction conditions. In an embodiment, the reaction may proceed for between 1 and 48 hours. However, if the reaction is assisted by microwave irradiation, then the reaction time may be as little as 1 to 30 seconds.

The reaction may be carried out in any suitable solvent system, such as, for example, toluene.

In an embodiment, the compounds of formula I are prepared from compounds of formula A1-A4 by the process defined herein.

The intermediate compounds of formulae A1-A4 can be prepared using any suitable synthetic technique known in the art.

Suitably, the compounds of formulae A1-A4 are synthesised by a cross-coupling reaction such as, for example, a Suzuki-Miyaura type reaction (see Suzuki, A. J. Organomet. Chem. 1999, 576, 147; Miyaura, N. Top. Curr. Chem. 2002, 219, 11; Bellina et al., Synthesis 2004, 15, 2419-2440; and/or Marion, N.; Nolan, S. P. Acc. Chem. Res. 2008, 41, 1440) or a stannane coupling reaction.

By way of example, a compound of formula A1 in which Ring B/Ring C and R₁/R₂ are the same is prepared by a Suzuki-Miyaura reaction involving:

(i) reacting a compound of formula (X)

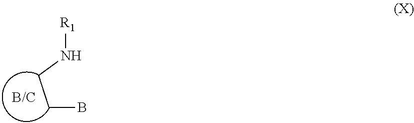

wherein
   R₁ and Ring B/C are as defined hereinbefore and B is a functional boron group;
with a compound of formula (XI)

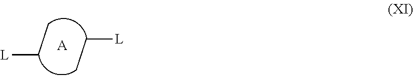

wherein
Ring A is as defined hereinbefore and L is a functional halide group or a functional sulfonyloxy group;
in the presence of a suitable solvent and under appropriate Suzuki-Miyaura reaction conditions; or

(ii) reacting a compound of formula (XII)

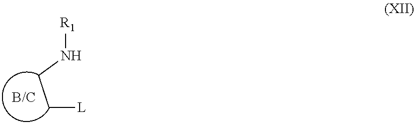

wherein
R₁ and Ring B/C are as defined hereinbefore and L is a functional halide
group or a functional sulfonyloxy group;
with a compound of formula (XIII):

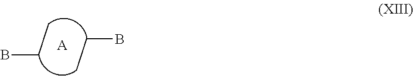

wherein
Ring A is as defined hereinbefore and B is a functional boron group;
in the presence of a suitable solvent and under appropriate Suzuki-Miyaura reaction conditions.

For such reactions, the functional halide group is a halogen group, with Cl, Br or I being preferred. Br or I are especially preferred.

A functional sulfonyloxy group is suitably of the formula —OSO₂R^{z} wherein R^{z} is an optionally fluorinated alkyl or aryl, preferably having 1 to 12 carbon atoms, such as, for example, methyl, trifluoromethyl or 4-methylphenyl, so that the sulfonyloxy group is mesylate, triflate or tosylate.

Suitably functional boron groups are well known in the art and include boronic acid, boronic acid ester (boronate) or a borane group. Preferably, the boron group is of the formula —B(OR′)(OR″), wherein R′ and R″ are H or alkyl with 1 to 12 C atoms, or R′ and R″ together form a cyclic aliphatic ring. Preferred boronate esters have the following structures:

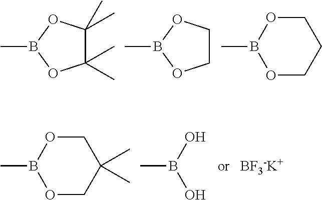

Suitable reaction conditions, catalysts and reagents for Suzuki-Miyaura coupling reactions are well known in the art.

It shall be appreciated that similar procedures can be used to prepare compounds of formulae A2-A4.

### Preparation of Polymers Comprising Monomers of Formula II and III as Defined Herein

In the preparation of polymers comprising monomers of formula II or III defined herein, the reaction conditions for performing the ring closure reaction to form a C—N bond in place of a C—H bond (and thereby form the fused pyrrole rings) are the same as those described above.

The polymers comprising monomers of the formulae B1, B2, B3, B4, C1, C2, C3 or C4 can be prepared using synthetic techniques known in the art.

Suitably, the compounds of the formulae B1, B2, B3, B4, C1, C2, C3 or C4 are synthesised by a cross-coupling reaction such as, for example, a Suzuki-Miyaura type reaction (see Suzuki, A. J. Organomet. Chem. 1999, 576, 147; Miyaura, N. Top. Curr. Chem. 2002, 219, 11; Bellina et al., Synthesis 2004, 15, 2419-2440; and/or Marion, N.; Nolan, S. P. Acc. Chem. Res. 2008, 41, 1440) or a stannane coupling reaction.

Thus, by way of example, a polymer comprising monomers of the formula B1 in which Ring B/Ring C and R₁/R₂ are the same can be prepared by a Suzuki-Miyaura reaction comprising:

(i) reacting a compound of formula (XX)

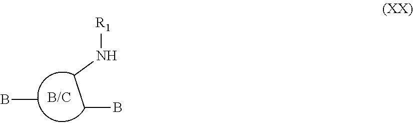

wherein
R₁ and Ring B/C are as defined hereinbefore and B is a functional boron group as defined hereinbefore;
with a compound of formula (XXI)

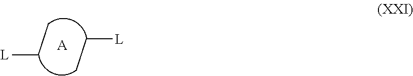

wherein
Ring A is as defined hereinbefore and L is a functional halide group or a functional sulfonyloxy group as defined hereinbefore;
in the presence of a suitable solvent and under appropriate Suzuki-Miyaura reaction coupling conditions; or

(ii) reacting a compound of formula (XXII)

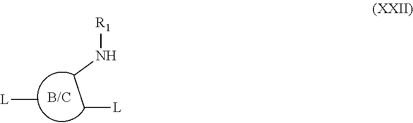

wherein
R₁ and Ring B/C are as defined hereinbefore; and L is a functional halide group or a functional sulfonyloxy group as defined hereinbefore;
with a compound of formula (XXIII)

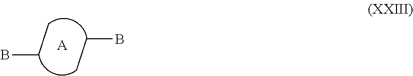

wherein
Ring A is as defined hereinbefore and B is a functional boron group as defined hereinbefore;
in the presence of a suitable solvent and under appropriate Suzuki-Miyaura reaction conditions.

It shall be appreciated that similar procedures can be used to prepare compounds of formulae B2, C1 or C2.

Compounds of Formula I and Polymers Comprising Monomers of formula II or III

In one aspect, the present invention additionally provides a compound of formula (I) as defined herein, wherein Ring A, Ring B, Ring C, R₁ and R₂ are as defined hereinbefore;

with the proviso that:

(i) wherein Ring A, Ring B, and Ring C are cannot all be phenyl;

(ii) Ring and Ring C are not both phenyl when Ring A is a group of formula:

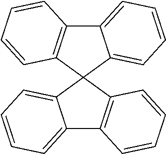 [SMILES: c1ccc2c(c1)-c1ccccc1C21c2ccccc2-c2ccccc21]

(iii) Ring A is not phenyl when both Ring B and Ring C have the formula:

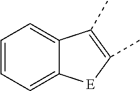

In an embodiment, the compounds of formula I are as defined above, with the additional proviso that:

(iv) Ring A is not naphthyl.

In a further embodiment, R₁ and R₂ are not both alkyl in the compounds of formula I.

In another embodiment, R₁ and R₂ are each independently selected from (2-20C)alkanoyl, (1-20C)alkyl-SO₂—; or a group

-Z¹-Q¹
wherein Z¹ is —CO— or —SO₂—; and
Q¹ is selected from aryl, heteroaryl, heterocyclyl, (3-8C)cycloalkyl, aryl-(1-10C)alkyl, heteroaryl-(1-10C)alkyl, heterocyclyl-(1-10C)alkyl, or (3-8C)cycloalkyl-(1-10C)alkyl; and wherein Q¹ is optionally substituted with one or more (1-20C)alkyl, (2-20C)alkenyl, (2-20C)alkynyl or (2-20C)alkanoyl groups;
and wherein a R₁ or R₂ substituent group is optionally further substituted by one or more substituents R^{a} as defined herein.

In a further aspect, the present invention provides a polymer comprising a monomeric component of formula II as defined herein, wherein Ring A, Ring B, Ring C are as defined herein, subject to the proviso that Rings A, B, and C are not all phenyl,

In a further aspect, the present invention provides a polymer comprising a monomeric component of formula II as defined herein, subject to the proviso that Rings A, B, and C are not all phenyl and R₁ and R₂ are not both alkyl.

In an embodiment of the polymer comprising monomers of formula II, R₁ and R₂ are each independently selected from (2-20C)alkanoyl, (1-20C)alkyl-SO₂—; or a group

-Z¹-Q¹
wherein Z¹ is —CO— or —SO₂—; and
Q¹ is selected from aryl, heteroaryl, heterocyclyl, (3-8C)cycloalkyl, aryl-(1-10C)alkyl, heteroaryl-(1-10C)alkyl, heterocyclyl-(1-10C)alkyl, or (3-8C)cycloalkyl-(1-10C)alkyl; and wherein Q¹ is optionally substituted with one or more (1-20C)alkyl, (2-20C)alkenyl, (2-20C)alkynyl or (2-20C)alkanoyl groups;
and wherein a R₁ or R₂ substituent group is optionally further substituted by one or more substituents R^{a} as defined herein.

In another aspect, the present invention provides a polymer comprising monomeric components of formula III wherein Ring A, Ring B, R₁ and R₂ are as defined herein.

Polymers comprising monomers of Formula II or III as defined herein may be homopolymers or co-polymers comprising one or more additional monomeric components.

Suitable co-monomers can be selected by those skilled in the art to provide a final polymer having the desired properties. For example, additional monomeric components may be added to alter the electronic properties of the polymer or its physical characteristics e.g. its solubility, hydrophilicity/hydrophobicity.

### Formulations

The present invention further provides a formulation comprising:
one or more oligomers of formula I as defined herein, or polymers comprising monomeric components of formula II or formula III as defined herein;
one or more solvents;
and optionally one or more binders, preferably organic binders, or precursors thereof.

In another aspect the present invention relates to a formulation comprising:
one or more oligomers of formula I as defined herein, or polymers comprising monomeric components of formula II or formula III as defined herein;
one or more binders, preferably organic binders, or precursors thereof; and optionally one or more solvents.

Suitable binders for use in such compositions are known in the art. Suitable binders are defined further in, for example, WO2008/011957, in particular page 31, line 13 to page 44, line 23 thereof, the relevant contents of which are incorporated herein by reference.

Suitable solvents for use in such systems are also known in the art.

Examples of such solvents are provided at page 45, line 35 to page 46, line 6 of WO2008/011957.

### Uses

In a further aspect, the present invention relates to the use of oligomers of formula I as defined herein and/or polymers comprising monomeric components of formula II or formula III as defined herein, or mixtures thereof, as materials for organic semi-conductor applications.

In another aspect, the present invention provides an organic semiconductor layer comprising one or more oligomers of formula I as defined herein and/or polymers comprising monomeric components of formula II or formula III as defined herein, or a formulation as defined herein.

The present invention further relates to a process for preparing an organic semiconductor layer as defined herein, comprising the steps of;
(i) depositing on a substrate a liquid layer of a formulation as defined herein;
(ii) forming from the liquid layer a solid layer which forms the organic semiconductor layer; and
(iii) optionally removing the layer form the substrate.

In a further aspect, the present invention relates to the use of oligomers of formula I as defined herein and/or polymers comprising monomeric components of formula II or formula III as defined herein, or mixtures thereof, or a formulation as defined herein or a organic semiconductor layer as defined herein in an electronic, optical or electro-optical component or device.

In a further aspect, the present invention relates to an electronic, optical or electro-optical component or device comprising oligomers of formula I as defined herein and/or polymers comprising monomeric components of formula II or formula III as defined herein, or mixtures thereof, or a formulation as defined herein or a organic semiconductor layer as defined herein.

As previously stated, the electronic, optical or electro-optical component or device may include, but is not limited to, an organic field effect transistor (OFET), thin film transistor (TFT), component of integrated circuitry (IC), radio frequency identification (RFID) tags, organic light emitting diodes (OLED), electroluminescence display, flat panel display, backlight, photodetector, sensor, logic circuit, memory element, capacitor, photovoltaic (PV) cell, photoconductor, and electrophotographic element.

### EXAMPLES

The invention will now be described in more detail in relation to the following illustrative examples.

### General Experimental

All reactions were carried out under an inert nitrogen atmosphere unless otherwise stated. Glassware for inert atmosphere reactions was oven-dried and cooled under a flow of nitrogen. Tetrahydrofuran (THF) was distilled over sodium wire and benzophenone, CH₂Cl₂, toluene and triethylamine were distilled over calcium hydride and dimethyl formamide (DMF) was dried over activated molecular sieves. All other solvents and reagents were purchased from commercial sources and used as supplied. ¹H NMR spectra were recorded on a 300, 400 or 500 MHz spectrometer; ¹³C NMR spectra were recorded on a 75, 100 or 125 MHz spectrometer. All chemical shift values are reported in ppm, with coupling constants in Hz. The notation of signals is: Proton: δ chemical shift in ppm (number of protons, multiplicity, J value(s), proton assignment). Carbon: δ chemical shift in ppm (carbon assignment). If assignment is ambiguous, for example in the case of overlapping aromatic signals, a range of shifts is reported. Routine TLC analysis was carried out on aluminium sheets coated with silica gel 60 F254, 0.2 mm thickness. Solvent systems were petroleum ether 40-60/ethyl acetate. Plates were viewed with a 254 nm ultraviolet lamp and dipped in aqueous potassium permanganate, p-anisaldehyde or DNP. Flash column chromatography was carried out on 40-63μ, 60 A silica gel. Low-resolution and high resolution mass spectra were obtained using electron impact ionisation (EI) and chemical ionisation (CI) techniques, or positive and/or negative electrospray ionisation (ES). Melting points were measured on a variable heater apparatus and are uncorrected. IR spectra were recorded on a FTIR spectrometer as evaporated films (from CH₂Cl₂) or neat, using sodium chloride windows.

### Example 1

### Synthesis of 5,11-Didodecyl-5,11-dihydroindolo[3,2-b]carbazole

### (i) Synthesis of 2-Bromo-N-dodecylaniline

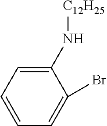

To activated powdered 3 Å molecular sieves (500 mg) in anhydrous N,N-dimethylformamide (100 mL), was added cesium hydroxide monohydrate (1.46 g, 8.7 mmol), and then the white suspension was vigorously stirred for 10 min. After 2-bromoaniline (1.5 g, 8.7 mmol) was added and followed by additional 30 min of stirring, 1-iodododecane (2.5 mL, 10.1 mmol) was added into the white suspension. The reaction was stirred for 20 h, filtered to remove the molecular sieves and undissolved inorganic salts, and rinsed several times with EtOAc. After the filtrate was concentrated to a nominal volume by blowing air, the residue was taken up in 1 N NaOH, and extracted with EtOAc (4×50 mL). The combined organic layers were washed with brine, dried over anhydrous magnesium sulfate, filtered, and concentrated under reduced pressure. The crude product was purified by column chromatography on silica gel (Pet ether-dichloromethane, 9:1) to afford the title compound (2.72 g, 8 mmol; 92%) as a pale yellow oil.

¹H NMR (CDCl₃) δ 7.46 (d, J=8 Hz, 1H), 7.21 (t, J=8 Hz, 1H), 6.67 (d, J=8 Hz, 1H), 6.59 (t, J=8 Hz, 1H), 4.33 (s, 1H), 3.18 (t, J=7 Hz, 2H), 1.55 (quint, J=7 Hz, 2H), 1.18 (m, 18H), 0.80 (t, J=7 Hz, 3H); ¹³C NMR (CDCl₃) δ 145.2, 132.3, 144.0, 128.5, 117.4, 111.2, 109.6, 43.9, 31.9, 29.7, 29.7, 29.6, 29.6, 29.4, 29.4, 29.3, 27.1, 22.7, 14.2. Mass spectrum (APCl): m/z ([M+]) 340.342.

### (ii) Synthesis of N²,N²″-Didodecyl-[1,1′:4,1″-terphenyl]-2,2″-diamine

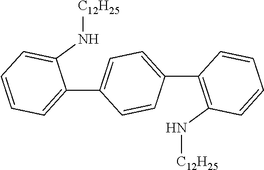

2-bromo-N-dodecylaniline (1.11 g, 5.4 mmol), benzene-1,4-diboronic acid (0.18 g, 1.8 mmol), Pd(PPh₃)₄ (0.13 g, 0.18 mmol), Na₂CO₃ (0.42 g, 6.5 mmol) in toluene (10 mL), EtOH (5 mL), and H₂O (5 mL). The mixture was degassed by freeze and pump and stirred at 80° C. under argon atmosphere for 3 days. The mixture was extracted with dichloromethane (5×50 mL). The combined organic layers were dried over anhydrous magnesium sulfate, filtered, and concentrated under reduced pressure. The crude product was purified by column chromatography on silica gel (Pet ether-dichloromethane, 9:1) to afford the title compound (1.02 g, 1.71 mmol; 95%) as a colourless solid.

¹H NMR (CDCl₃) δ 7.43 (s, 4H), 7.18 (t, J=8 Hz, 2H), 7.09 (d, J=8 Hz, 2H), 6.74 (m, 4H), 3.98 (s, 2H), 3.05 (t, J=7 Hz, 4H), 1.17 (m, 36H), 0.80 (t, J=7 Hz, 6H). Mass spectrum (APCl): m/z ([M+]) 597.

### Synthesis of 5,11-Didodecyl-5,11-dihydroindolo[3,2-b]carbazole

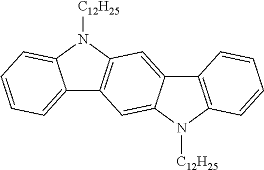

The N²,N²″-didodecyl-[1,1′:4′,1″-terphenyl]-2,2″-diamine (100 mg, 0.17 mmol) and Pd(OAc)₂ (4 mg, 10 mol %) were stirred, unless otherwise stated, in toluene (0.05 M) at room temperature for 1 h. Phenyliodonium diacetate (PIDA, 0.4 mmol) was then added and the reaction mixture was stirred at room temperature overnight. The mixture was extracted with dichloromethane (5×50 mL). The combined organic layers were dried over anhydrous magnesium sulfate, filtered, and concentrated under reduced pressure. The crude product was purified by column chromatography on silica gel (Pet ether-dichloromethane, 9:1) to afford the title compound (80 mg, 0.13 mmol; 79%) as a pale yellow solid.

¹H NMR (CDCl₃) δ 8.15 (d, J=8 Hz, 2H), 7.92 (s, 2H), 7.39 (t, J=8 Hz, 2H), 6.36 (d, J=8 Hz, 2H), 7.13 (t, J=8 Hz, 2H), 4.31 (t, J=7 Hz, 4H), 1.88 (quint, J=7 Hz, 4H), 1.19 (m, 40H), 0.79 (t, J=7 Hz, 6H); ¹³C NMR (CDCl₃) δ 141.7, 136.0, 144.0, 125.6, 122.8, 122.8, 120.2, 117.9, 108.4, 98.7, 43.3, 31.9, 29.6, 29.6, 29.6, 29.5, 29.4, 29.4, 28.9, 27.4, 27.4, 22.7, 14.2. Mass spectrum (APCl): m/z ([M+]) 593.

### Example 2

### Synthesis of 5,8-Didodedecyl-14,14-diethyl-8,14-dihydro-5H-cyclopenta[1,2-b:5,4-b′]dicarbazole

### (i) Synthesis of 2,7-dibromo-9,9-diethyl-9H-fluorene

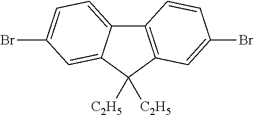 [SMILES: CCC1(CC)c2cc(Br)ccc2-c2ccc(Br)cc21]

A 5 g amount (15 mmol) of the commercially available 2-bromofluorene were dissolved in 85 mL of DMSO. To the solution 0.85 g of triethylbenzylammonium chloride and 0.85 g of tetra-n-butylammonium chloride were added as phase-transfer catalysts. After the addition of 50 mL of 25 N NaOH solution, 6.5 mL (86 mmol) of bromoethane was added. The reaction mixture was stirred at 100° C. After 12 h, water was added until the two phases mixed. The solution was extracted with diethyl ether (5×50 mL), washed with water, and dried over anhydrous magnesium sulfate before the solvent was evaporated. The crude product was purified by column chromatography on silica gel (Pet ether-dichloromethane, 4:1) to afford the title compound (5.42 g, 14.2 mmol; 95%) as white crystals.

¹H NMR (CDCl₃) δ 7.38 (d, J=7.8 Hz, 2H), 7.31 (d, J=7.8 Hz, 2H), 7.30 (s, 2H), 1.84 (q, J=8 Hz, 4H), 0.15 (t, J=8 Hz, 6H); ¹³C NMR (CDCl₃) δ 151.8, 139.5, 130.2, 126.3, 121.5, 121.1, 56.8, 32.6, 8.4;

### (ii) Synthesis of 2,2′-(9,9-diethyl-9H-fluorene-2,7-diyl)bis(4,4,5,5-tetramethyl-1,3,2-dioxaborolane)

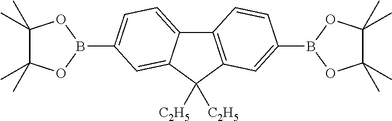

A 1 g amount (2.6 mmol) of 2,7-dibromo-9,9-diethyl-9H-fluorene was dissolved in 100 mL of dried THF under argon. The solution was cooled to −78° C. before 2.3 mL (6.3 mmol) of n-BuLi (2.5 M solution in hexane) was added dropwise. The reaction mixture was stirred for 20 min before 1.28 mL (6.3 mmol) of 2-isopropoxy-4,4,5,5-tetramethyl-1,3,2-dioxaborolane was added. The reaction mixture was allowed to warm to room temperature and stirred for 12 h before it was poured into ice water. The solution was extracted with diethyl ether (5×50 mL), the organic phase washed with brine and dried over anhydrous magnesium sulfate before the solvent was evaporated. Purification was carried out by column chromatography on silica gel with hexane: acetic ester (10:1) as eluent. The crude product was purified by column chromatography on silica gel (Pet ether-dichloromethane, 4:1) to afford the title compound (0.99 g, 2.1 mmol; 80%) as a colourless solid.

¹H NMR (CDCl₃) δ 7.59 (d, J=7.8 Hz, 2H), 7.51 (s, 2H), 7.49 (d, J=7.8 Hz, 2H), 1.85 (q, J=8 Hz, 4H), 1.12 (s, 24H), 0.02 (t, J=8 Hz, 6H); ¹³C NMR (CDCl₃) δ 149.6, 144.4, 133.7, 129.0, 119.4, 83.7, 56.3, 32.6, 25.0, 8.6; Mass spectrum: m/z ([M+]) 474.

### Synthesis of 2,2′-(9,9-diethyl-9H-fluorene-2,7-diyl)bis(N-dodecylaniline)

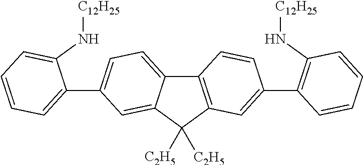

2-bromo-N-dodecylaniline (432 mg, 1.27 mmol), 2,2′-(9,9-diethyl-9H-fluorene-2,7-diyl)bis(4,4,5,5-tetramethyl-1,3,2-dioxaborolane) (200 mg, 0.42 mmol), Pd(PPh₃)₄ (48.7 g, 0.04 mmol), Na₂CO₃ (358 mg, 3.38 mmol) in toluene (30 mL), EtOH (10 mL), and H₂O (10 mL). The mixture was degassed by freeze and pump and stirred at 80° C. under argon atmosphere for 3 days. The mixture was extracted with dichloromethane (5×50 mL). The combined organic layers were dried over anhydrous magnesium sulfate, filtered, and concentrated under reduced pressure. The crude product was purified by column chromatography on silica gel (Pet ether-dichloromethane, 9:1) to afford the title compound (256 mg, 0.35 mmol; 82%) as a pale yellow solid.

¹H NMR (CD₂Cl₂) δ 8.72 (d, J=7.8 Hz, 2H), 7.36 (s, 2H), 7.29 (d, J=7.8 Hz, 2H), 7.12 (t, J=7.8 Hz, 2H), 7.07 (d, J=7.8 Hz, 2H), 7.62 (m, 6H), 3.85 (s, 4H), 1.98 (q, J=8 Hz, 4H), 1.43 (quint, J=8 Hz, 4H), 1.17 (m, 40H), 0.79 (t, J=8 Hz, 6H), 0.31 (t, J=8 Hz, 6H); ¹³C NMR (CD₂Cl₂) δ 149.8, 144.8, 139.5, 137.7, 129.2 127.8, 127.4, 127.1, 123.1, 119.3, 115.7, 109.5, 55.4, 43.2, 31.9, 31.2, 28.9, 28.9, 28.8, 28.8, 28.6, 28.6, 28.6, 26.4, 21.9, 13.1, 7.7. Mass spectrum (APCl): m/z ([M+]) 742.

### (iii) Synthesis of 5,8-Didodecyl-14,14-diethyl-8,14-dihydro-5H-cyclopenta[1,2-b:5,4-b′]dicarbazole

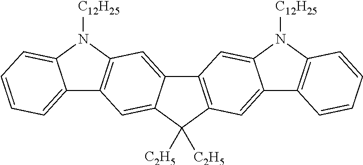

2,2′-(9,9-diethyl-9H-fluorene-2,7-diyl)bis(N-dodecylaniline) (100 mg, 0.14 mmol) and Pd(OAc)₂ (3 mg, 10 mol %) were stirred, unless otherwise stated, in toluene (0.05 M) at room temperature for 1 h. Phenyliodonium diacetate (PIDA, 0.3 mmol) was then added and the reaction mixture was stirred at room temperature overnight. The mixture was extracted with dichloromethane (5×50 mL). The combined organic layers were dried over anhydrous magnesium sulfate, filtered, and concentrated under reduced pressure. The crude product was purified by column chromatography on silica gel (Pet ether-dichloromethane, 9:1) to afford the title compound (30 mg, 0.04 mmol; 30%) as a colourless solid. ¹H NMR (CD₂Cl₂) δ 8.05(d, J=7.8 Hz, 2H), 7.91 (s, 2H), 7.72 (s, 2H), 7.32 (m, 4H), 7.12 (t, J=7.8 Hz, 2H), 4.31 (t, J=8 Hz, 4H), 2.16 (q, J=8 Hz, 4H), 1.98 (quint, J=8 Hz, 4H), 1.41 (quint, J=8 Hz, 4H), 1.98 (quint, J=8 Hz, 4H), 1.32 (m, 4H), 1.20 (m, 24H), 0.80 (t, J=8 Hz, 6H), 0.30 (t, J=8 Hz, 6H); ¹³C NMR (CD₂Cl₂) δ 142.4, 141.5, 141.0, 140.9, 125.6, 123.3, 123.1, 120.2, 119.0, 114.7, 109.1, 99.6, 55.1, 43.7, 34.5, 32.3, 30.1, 30.0, 29.9, 29.8, 29.5, 27.8, 23.1, 14.3, 8.9. Mass spectrum (APCl): m/z ([M+]) 737.

### Example 3

### Synthesis of 5,11-bis(4-octylphenyl)-5,11-dihydroindolo[3,2-b]carbazole

### (i) Synthesis of 2-bromo-N-(4-octylphenyl)aniline

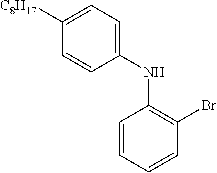

An over-dried schlenk was charged with 4-octylaniline (0.6 g, 2.9 mmol), 1-bromo-2-iodobenzene (1.0 g, 4.8 mmol), Pd(OAc)₂ (3.3 10⁻³ g, 0.014 mmol), (oxybis(2,1-phenylene))bis(diphenylphosphine) (DPEPhos) (2.4 10⁻² g, 0.044 mmol), evacuated and then filled with argon. The resulting mixture was stirred for 5 min at room temperature. Then the flask was opened and t-BuONa (0.4 g, 3.2 mmol) was added and the tube schlenk was evacuated and filled with argon. Dried toluene (10 mL) was added and the mixture was heated at 100° C. for 24 h. The mixture was then cooled to room temperature and taken up in dichloromethane. The resulting solution was dried over anhydrous magnesium sulfate, filtered, and concentrated under reduced pressure. The crude product was purified by column chromatography on silica gel (Pet ether-dichloromethane, 4:1) to afford the title compound (0.92 g, 2.6 mmol; 88%) as a colourless oil. ¹H NMR (CDCl₃) δ 7.51 (dd, J=7.8 Hz, J=1.5 Hz, 1H), 7.20-7.08 (m, 6H), 6.71 (td, J=7.8 Hz, J=1.5 Hz, 1H), 5.52 (s, 1H), 2.59 (t, J=7.5 Hz, 2H), 1.62 (pent, J=7.5 Hz, 2H), 1.43-1.17 (m, 10H), 0.90 (t, J=7.5 Hz, 3H). ¹³C NMR (CD₂Cl₂) δ 142.1, 138.9, 137.9, 132.8, 129.3, 128.1, 121.2, 120.2, 115.0, 111.5, 35.3, 31.9, 31.6, 29.5, 29.3, 29.3, 22.7, 14.1. Mass spectrum (APCl): m/z ([M+]) 360.

### Synthesis of N²,N²″-bis(4-octylphenyl)-[1,1′:4′,1″-terphenyl]-2,2″-diamine

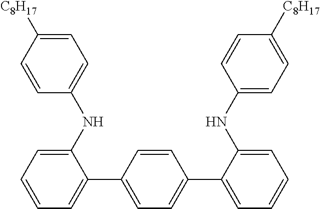

2-bromo-N-(4-octylphenyl)aniline (652 mg, 1.8 mmol), benzene-1,4-diboronic acid (100 mg, 0.6 mmol), Pd(PPh₃)₄ (70 mg, 0.06 mmol), Na₂CO₃ (254 mg, 2.4 mmol) in toluene (20 mL), EtOH (10 mL), and H₂O (10 mL). The mixture was degassed by freeze and pump and stirred at 80° C. under argon atmosphere for 3 days. The mixture was extracted with dichloromethane (5×50 mL). The combined organic layers were dried over anhydrous magnesium sulfate, filtered, and concentrated under reduced pressure. The crude product was purified by column chromatography on silica gel (Pet ether-dichloromethane, 4:1) to afford the title compound (344 mg, 0.53 mmol; 86%) as a colourless solid. ¹H NMR (CDCl₃) δ 7.63 (s, 2H), 7.36 (m, 6H), 7.45-7.31 (m, 12H), 5.75 (s, 2H), 2.66 (t, J=7.5 Hz, 4H), 1.71 (q, J=6.5 Hz, 4H), 1.39 (m, 20H), 1.00 (t, J=7 Hz, 6H). ¹³C NMR (CDCl₃) δ 141.2, 140.8, 138.4, 136.5, 131.0, 130.3, 130.0, 129.4, 129.3, 128.5, 120.6, 120.4, 119.5, 118.8, 117.1, 35.4, 32.0, 31.8, 29.7, 29.5, 29.4, 22.8, 14.3. Mass spectrum (APCl): m/z ([M+]) 636.

### Synthesis of 5,11-bis(4-octylphenyl)-5,11-dihydroindolo[3,2-b]carbazole

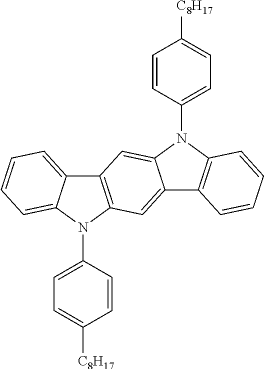

N²,N²″-bis(4-octylphenyl)[1,1′:4′,1″-terphenyl]-2,2″-diamine (50 mg, 0.08 mmol) and Pd(OAc)₂ (4 mg, 10 mol %) were stirred, unless otherwise stated, in toluene (0.05 M) at room temperature for 1 h. Dimethyl sulfoxide (DMSO, 15 mg, 0.20 mmol) was then added and the reaction mixture was stirred at 80° C. overnight. The mixture was extracted with dichloromethane (5×50 mL). The combined organic layers were dried over anhydrous magnesium sulfate, filtered, and concentrated under reduced pressure. The crude product was purified by column chromatography on silica gel (Pet ether-dichloromethane, 9:1) to afford the title compound (26 mg, 0.04 mmol; 52%) as a pale yellow solid. ¹H NMR (CDCl₃): δ 8.12 (d, J=7.6 Hz, 2H), 8.05 (s, 2H), 7.58 (d, J=8.3 Hz, 4H), 7.47 (d, J=8.3 Hz, 4H), 7.39-7.40 (m, 4H), 7.19-7.21 (m, 2H), 2.78 (t, J=7.8 Hz, 4H), 1.78 (pent, J=7.4 Hz, 4H), 1.30-1.50. (m, 20H), 0.92 (m, 6H). ¹³C NMR (CDCl₃) δ 141.7, 141.5, 136.4, 134.9, 129.2, 126.2, 125.2, 122.6, 122.5, 119.4, 118.4, 108.7, 99.0, 35.0, 31.2, 30.8, 28.8, 28.7, 28.6, 22.0, 13.0. Mass spectrum (APCl): m/z ([M+]) 632.

### Example 4

### Synthesis of 14,14-diethyl-5,8-bis(4-octylphenyl)-8,14-dihydro-5H-cyclopenta[1,2-b:5,4-b′]dicarbazole

### (i) Synthesis of 2,2′-(9,9-diethyl-9H-fluorene-2,7-diyl)bis(N-(4-octylphenyl)aniline)

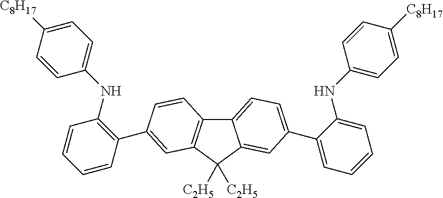

2-bromo-N-(4-octylphenyl)aniline (228 mg, 0.63 mmol; prepared as described in Example 3—step (i)), 2,2′-(9,9-diethyl-9H-fluorene-2,7-diyl)bis(4,4,5,5-tetramethyl-1,3,2-dioxaborolane) (100 mg, 0.21 mmol), Pd(PPh₃)₄ (24 mg, 0.02 mmol), K₂CO₃ (161 mg, 1.68 mmol) in toluene (30 mL), and H₂O (10 mL). The mixture was degassed by freeze and pump and stirred at 80° C. under argon atmosphere for 3 days. The mixture was extracted with dichloromethane (5×50 mL). The combined organic layers were dried over anhydrous magnesium sulfate, filtered, and concentrated under reduced pressure. The crude product was purified by column chromatography on silica gel (Pet ether-dichloromethane, 9:1) to afford the title compound (109 mg, 0.14 mmol; 38° A)) as a colourless solid. ¹H NMR (CD₂Cl₂) δ 7.82 (d, J=7.5 Hz, 2H), 7.49 (dd, J=7.5 Hz, J=1.5 Hz, 2H), 7.45 (s, 2H), 7.37 (td, J=7.5 Hz, J=1.5 Hz, 4H), 7.28 (td, J=7.5 Hz, J=1.5 Hz, 2H), 7.09 (d, J=8 Hz, 4H), 7.03 (td, J=7.5 Hz, J=1.5 Hz, 2H), 6.97 (d, J=8 Hz, 4H), 7.12 (t, J=7.8 Hz, 2H), 5.72 (s, 2H), 2.57 (t, J=7.5 Hz, 4H), 1.99 (q, J=7.5 Hz, 4H), 1.61 (pent, J=7.5 Hz, 4H), 1.42-1.25 (m, 20H), 0.92 (t, J=7.5 Hz, 6H), 0.41 (t, J=7.5 Hz, 6H); ¹³C NMR (CD₂Cl₂) 6151.2, 141.5, 141.2, 140.8, 138.4, 136.3, 132.2, 131.2, 129.5, 128.5, 128.5, 124.3, 121.1, 120.4, 118.5, 117.8, 117.6, 56.6, 35.6, 32.9, 32.3, 32.1, 29.9, 29.7, 23.1, 14.3, 8.9, 8.9. Mass spectrum (APCl): m/z ([M+]) 781.

### (ii) Synthesis of 14,14-diethyl-5,8-bis(4-octylphenyl)-8,14-dihydro-5H-cyclopenta[1,2-b:5,4-b′]dicarbazole

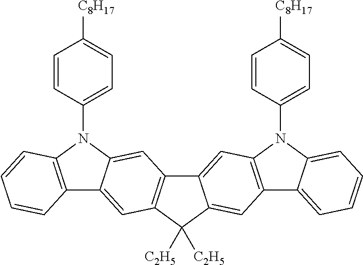

2,2′-(9,9-diethyl-9H-fluorene-2,7-diyl)bis(N-(4-octylphenyl)aniline) (40 mg, 0.05 mmol) and Pd(OAc)₂ (2 mg, 20 mol %) were stirred, unless otherwise stated, in toluene (0.05 M) at RT for 1 h. Cu(OAc)₂ (45 mg, 0.25 mmol) was then added and the reaction mixture was stirred at 80° C. for 48 h. The mixture was extracted with dichloromethane (5×50 mL). The combined organic layers were dried over anhydrous magnesium sulfate, filtered, and concentrated under reduced pressure. The crude product was purified by column chromatography on silica gel (Pet ether-dichloromethane, 9:1) to afford the title compound (29 mg, 0.04 mmol; 73%) as a colourless solid. ¹H NMR (CD₂Cl₂) δ 8.15 (d, J=8 Hz, 2H), 8.08 (s, 2H), 7.66 (s, 2H), 7.51 (d, J=8 Hz, 4H), 7.45 (d, J=8 Hz, 4H), 7.38-7.33 (m, 4H), 7.27 (t, J=8 Hz, 2H), 2.77 (t, J=7.5 Hz, 4H), 2.26 (q, J=7.5 Hz, 4H), 1.75 (pent, J=7.5 Hz, 4H), 1.49-1.29 (m, 20H), 0.92 (t, J=7.5 Hz, 6H), 0.40 (t, J=7.5 Hz, 6H). ¹³C NMR (CD₂Cl₂) δ 143.3, 143.0, 142.1, 141.6, 141.2, 135.6, 130.3, 127.4, 125.8, 123.7, 123.4, 120.1, 120.0, 114.5, 110.0, 100.8, 55.1, 36.1, 34.5, 32.3, 31.9, 29.9, 29.8, 29.7, 23.1, 14.3, 8.8. Mass spectrum (APCl): m/z ([M+]) 777. Elemental analysis calcd (%) for C₅₇H₆₄N₂: C 88.09, H 8.30, N 3.60. found: C, 87.58; H, 7.93; N, 3.66.

### Example 5

### Synthesis of 5,8-bis(4-octylphenyl)-5,8-dihydrothieno[3,2-b:4,5-b′]dicarbazole

### (i) Synthesis of N-(4-octylphenyl)-2-(4,4,5,5-tetramethyl-1,3,2-dioxaborolan-2-yl)aniline

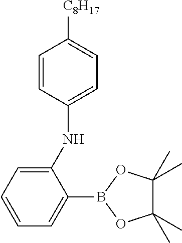

2-bromo-N-(4-octylphenyl)aniline (1.0 g, 2.78 mmol), 2-Dicyclohexylphosphino-2′-(N,N-dimethylamino)biphenyl (32.8 mg, 0.08 mmol), Pd(OAc)₂ (6.2 mg, 0.03 mmol), N,N,N-triethylamine (1.1 g, 11.1 mmol, 1.5 mL) were added and stirred in 1,4-dioxane (50 mL) under an argon atmosphere for 15 minutes. 4,4,5,5-tetramethyl-1,3,2-dioxaborolane (712.0 mg, 5.56 mmol, 0.4 mL) was then added via a syringe and the mixture was stirred at 90° C. for 12 hours. The crude product was purified by column chromatography on silica gel (Pet ether-dichloromethane, 4:1, then dichloromethane) to afford the title compound (120 mg, 0.3 mmol; 10%) as a yellow oil. ¹H NMR (CD₂Cl₂) δ 7.82 (d, J=7 Hz, 2H), 7.42-7.14 (m, 5H), 6.88 (t, J=7 Hz, 1H), 5.87 (s, 1H, NH), 2.75-2.70 (t, J=7 Hz, 2H), 1.74 (m, 2H), 1.50 (m, 30H), 1.05 (t, J=7 Hz, 3H). ¹³C NMR (CD₂Cl₂) δ 151.7, 140.5, 137.8, 133.1, 129.7, 121.4, 119.1, 118.4, 117.4, 113.3, 84.5, 35.9, 32.6, 30.0, 25.3, 23.3, 14.6. Mass spectrum (APCl): m/z ([M+]) 408.

### (ii) Synthesis of 2,2′-(dibenzo[b,d]thiophene-3,7-diyl)bis(N-(4-octylphenyl)aniline)

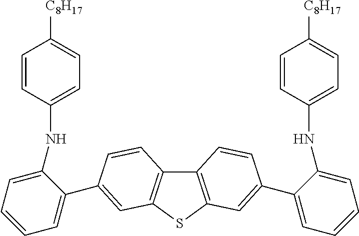

N-(4-octylphenyl)-2-(4,4,5,5-tetramethyl-1,3,2-dioxaborolan-2-yl)aniline (105 mg, 0.26 mmol), 3,7-dibromodibenzo[b,d]thiophene (40 mg, 0.12 mmol), PdCl₂(dppf) (5 mg, 0.01 mmol), K₃PO₄ (199 mg, 0.94 mmol) in dioxane (30 mL), and H₂O (5 mL). The mixture was degassed by freeze and pump and stirred at 90° C. under argon atmosphere for 2 days. The mixture was extracted with dichloromethane (5×50 mL). The combined organic layers were dried over anhydrous magnesium sulfate, filtered, and concentrated under reduced pressure. The crude product was purified by column chromatography on silica gel (Pet ether-dichloromethane, 9:1) to afford the title compound (56 mg, 0.08 mmol; 68%) as a colourless solid. ¹H NMR (acetone-d6) δ 8.15 (d, J=8 Hz, 2H), 7.87 (s, 2H), 7.45 (d, J=8 Hz, 2H), 7.21 (t, J=8 Hz, 2H), 7.14 (t, J=8 Hz, 2H), 6.90 (d, J=8 Hz, 4H), 6.83 (d, J=8 Hz, 4H), 6.42 (s, 2H, NH), 2.37 (t, J=7 Hz, 4H), 1.42 (pent, J=7 Hz, 4H), 1.25-0.92 (m, 20H), 0.73 (t, J=7 Hz, 6H). ¹³C NMR (acetone-d6) δ 143.4, 142.8, 141.4, 140.1, 136.3, 135.7, 133.2, 132.6, 130.5, 129.9, 127.6, 124.7, 123.3, 122.6, 120.0, 119.6, 55.5, 36.5, 33.3, 23.9, 23.5, 21.7, 15.0, 12.3. Mass spectrum (APCl): m/z ([M+]) 743.10.

### (iii) Synthesis of 5,8-bis(4-octylphenyl)-5,8-dihydrothieno[3,2-b:4,5-b′]dicarbazole

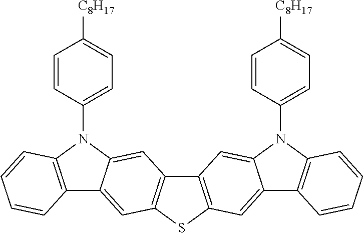

2,2′-(dibenzo[b,d]thiophene-3,7-diyl)bis(N-(4-octylphenyl)aniline) (45 mg, 0.06 mmol) and Pd(OAc)₂ (3 mg, 20 mol %) were stirred, unless otherwise stated, in toluene (0.05 M) at RT for 1 h. Cu(OAc)₂ (53 mg, 0.29 mmol) was then added and the reaction mixture was stirred at 80° C. for 48 h. The mixture was extracted with dichloromethane (5×50 mL). The combined organic layers were dried over anhydrous magnesium sulfate, filtered, and concentrated under reduced pressure. The crude product was purified by column chromatography on silica gel (Pet ether-dichloromethane, 9:1) to afford the title compound (39 mg, 0.05 mmol; 87%) as a colourless solid. ¹H NMR (CD₂Cl₂) δ 8.44 (s, 2H), 8.16 (m, 4H), 8.08 (d, J=8 Hz, 2H), 7.56 (d, J=8 Hz, 4H), 7.48 (d, J=8 Hz, 4H), 7.41 (t, J=8 Hz, 2H), 7.31 (t, J=8 Hz, 2H), 2.85 (t, J=7.5 Hz, 4H), 1.81 (m, J=7.5 Hz, 4H), 1.36-1.25 (m, 20H), 0.93 (t, J=7.5 Hz, 6H).

### Example 6

### Synthesis of 5,8-didodecyl-5,8-dihydrothieno[3,2-b:4,5-b′]dicarbazole

### (i) Synthesis of 2,2′-(dibenzo[b,d]thiophene-3,7-diyl)bis(N-dodecylaniline)

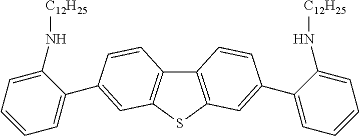

N-dodecyl-2-(4,4,5,5-tetramethyl-1,3,2-dioxaborolan-2-yl)aniline (100 mg, 0.26 mmol), 3,7-dibromodibenzo[b,d]thiophene (40 mg, 0.12 mmol), PdCl₂(dppf) (5 mg, 0.01 mmol), K₃PO₄ (199 mg, 0.94 mmol) in dioxane (30 mL), and H₂O (5 mL). The mixture was degassed by freeze and pump and stirred at 90° C. under argon atmosphere for 2 days. The mixture was extracted with dichloromethane (5×50 mL). The combined organic layers were dried over anhydrous magnesium sulfate, filtered, and concentrated under reduced pressure. The crude product was purified by column chromatography on silica gel (Pet ether-dichloromethane, 9:1) to afford the title compound (45 mg, 0.06 mmol; 55%) as a colourless solid. ¹H NMR (CD₂Cl₂) δ 8.25 (d, J=8 Hz, 2H), 7.91 (s, 2H), 7.55 (d, J=8 Hz, 2H), 7.25 (t, J=7.5 Hz, 2H), 7.17 (d, J=7.8 Hz, 2H), 6.76 (m, 4H), 3.99 (5, 2H), 3.11 (t, J=7.5 Hz, 4H), 1.54 (pent, J=7.5 Hz, 4H), 1.24 (m, 36H), 0.87 (t, J=7 Hz, 6H). ¹³C NMR (CD₂Cl₂) δ 146.2, 140.9, 139.1, 134.8, 130.8, 129.5, 127.5, 126.6, 124.0, 122.4, 117.1, 111.0, 44.5, 32.5, 30.2, 30.2, 30.2, 29.9, 29.9, 27.7, 23.3, 14.5. Mass spectrum (APCl): m/z ([M+]) 704.

### (ii) Synthesis of 5,8-didodecyl-5,8-dihydrothieno[3,2-b:4,5-b]dicarbazole

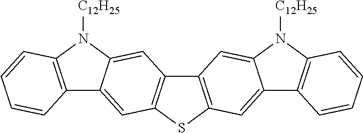

2,2′-(dibenzo[b,d]thiophene-3,7-diyl)bis(N-dodecylaniline) (45 mg, 0.06 mmol) and Pd(OAc)₂ (1 mg, 10 mol %) were stirred, unless otherwise stated, in toluene (0.05 M) at RT for 1 h. Iodobenzene diacetate (49 mg, 0.15 mmol) was then added and the reaction mixture was stirred at RT overnight. The mixture was extracted with dichloromethane (5×50 mL). The combined organic layers were dried over anhydrous magnesium sulfate, filtered, and concentrated under reduced pressure. The crude product was purified by column chromatography on silica gel (Pet ether-dichloromethane, 9:1) to afford the title compound (2 mg, 0.003 mmol; 4%) as a colourless solid. ¹H NMR (CDCl₃) δ 8.52 (s, 2H), 8.28 (t, J=8 Hz, 2H), 8.18 (d, J=8 Hz, 2H), 8.11 (s, 2H), 7.87 (d, J=8 Hz, 2H), 7.48 (t, J=8 Hz, 2H), 4.42 (t, J=7 Hz, 4H), 1.97 (pent, J=7 Hz, 4H), 1.24 (m, 36H), 0.88 (t, J=7 Hz, 6H).

### Example 7

### Synthesis of 5,8-didodecyl-5H-cyclopenta[1,2-b:5,4-b′]dicarbazol-14(8H)-one

### (i) Synthesis of 2,7-bis(2-(dodecylamino)phenyl)-9H-fluoren-9-one

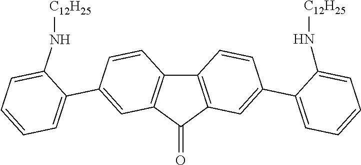

N-dodecyl-2-(4,4,5,5-tetramethyl-1,3,2-dioxaborolan-2-yl)aniline (101 mg, 0.26 mmol), 2,7-dibromo-9H-fluoren-9-one (40 mg, 0.12 mmol), PdCl₂(dppf) (5 mg, 0.01 mmol), K₃PO₄ (201 mg, 0.94 mmol) in dioxane (30 mL), and H₂O (5 mL). The mixture was degassed by freeze and pump and stirred at 90° C. under argon atmosphere for 2 days. The mixture was extracted with dichloromethane (5×50 mL). The combined organic layers were dried over anhydrous magnesium sulfate, filtered, and concentrated under reduced pressure. The crude product was purified by column chromatography on silica gel (Pet ether-dichloromethane, 4:1, then dichloromethane) to afford the title compound (20 mg, 0.04 mmol; 30%) as an orange solid. ¹H NMR (CDCl₃) δ 7.71 (s, 2H), 7.53 (d, J=8 Hz, 2H), 7.20 (t, J=8 Hz, 2H), 7.05 (d, J=8 Hz, 2H), 6.76 (m, 6H), 3.72 (s, 2H), 3.04 (t, J=8 Hz, 4H), 1.54 (pent, J=8 Hz, 4H), 1.21 (m, 36H), 0.80 (t, J=8 Hz, 6H). ¹³C NMR (CDCl₃) δ 145.3, 143.0, 140.9, 135.7, 135.1, 130.0, 129.3, 126.1, 125.5, 120.8, 120.3, 116.8, 110.7, 44.0, 31.9, 29.6, 29.6, 29.6, 29.4, 27.2, 22.7, 14.5. Mass spectrum (APCl): m/z ([M+]) 700.

### (ii) Synthesis of 5,8-didodecyl-5H-cyclopenta[1,2-b:5,4-b′]dicarbazol-14(8H)-one

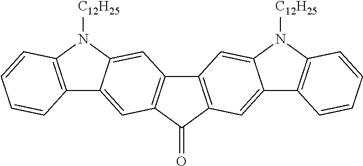

2,7-bis(2-(dodecylamino)phenyl)-9H-fluoren-9-one (20 mg, 0.03 mmol) and Pd(OAc)₂ (1 mg, 10 mol %) were stirred, unless otherwise stated, in toluene (0.05 M) at RT for 1 h. Iodobenzene diacetate (22 mg, 0.7 mmol) was then added and the reaction mixture was stirred at RT overnight. The mixture was extracted with dichloromethane (5×50 mL). The combined organic layers were dried over anhydrous magnesium sulfate, filtered, and concentrated under reduced pressure. The crude product was purified by column chromatography on silica gel (Pet ether-dichloromethane, 4:1, then dichloromethane) to afford the title compound (15 mg, 0.02 mmol; 75%) as a yellow solid. ¹H NMR (acetone-d6) δ 7.56 (s, 2H), 7.43 (d, J=8 Hz, 2H), 7.24 (s, 2H), 6.82 (d, J=8 Hz, 2H), 6.68 (t, J=8 Hz, 2H), 6.48 (t, J=8 Hz, 2H), 3.72 (t, J=7 Hz, 4H), 1.18 (pent, J=7.5 Hz, 4H), 0.61-0.42 (m, 36H), 0.03 (t, J=7.5 Hz, 6H). ¹³C NMR (acetone-d6) δ 143.3, 143.0, 142.1, 141.6, 141.2, 135.6, 130.3, 127.4, 125.8, 123.7, 123.4, 120.1, 120.0, 114.5, 110.0, 100.8, 55.1, 36.1, 34.5, 32.3, 31.9, 29.9, 29.8, 29.7, 23.1, 14.3, 8.8.

### Examples 8 to 15

### General Methods

### General Method 1

### synthesis of 2-bromo-N-dodecylaniline

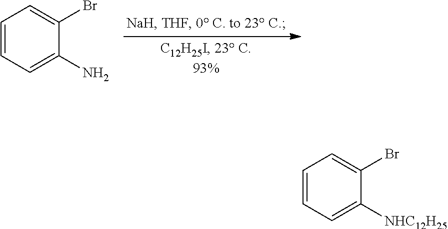

Sodium hydride (60% dispersion in mineral oil, 1.44 g, 36 mmol, 1.2 equiv.) was added to a solution of 2-bromoaniline (5.16 g, 30 mmol, 1 equiv.) in 60 mL THF at 0° C. The reaction was allowed to warm to 23° C. and stirred for 2 hours before 1-iodododecane (8.88 mL, 36 mmol, 1.2 equiv.) was added. After stirring for 16 hours the reaction was quenched with 60 mL water and extracted with ethyl acetate (3×60 mL). The combined organic extracts were dried over Na₂SO₄, the volatiles removed in vacuo and the crude product was purified by chromatography on silica gel (petroleum ether 40-60) to give 2-bromo-N-dodecylaniline (9.56 g, 28.1 mmol, 93%) as a pale yellow oil. ¹H NMR (400 MHz, CDCl₃) δ 7.42 (1H, dd, J=7.8, 1.5 Hz), 7.19 (1H, ddd, J=8.2, 7.1, 1.5 Hz), 6.64 (1H, dd, J=8.2, 1.5 Hz), 6.56 (1H, td, J=7.6, 1.5 Hz), 4.28 (1H, br. s.), 3.08-3.22 (2H, m), 1.68 (2H, quin, J=7.3 Hz), 1.20-1.48 (18H, m), 0.90 (3H, t, J=6.6 Hz).

### General Method 2

### synthesis of 2-bromo-N-(4-decylphenyl)aniline

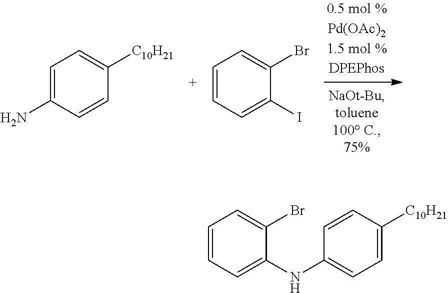

To a degassed solution of 4-decylaniline (1.29 g, 5.53 mmol, 1.2 eqiuv.), 1-bromo-2-iodobenzene (0.591 mL, 4.61 mmol, 1 equiv.), palladium acetate (5.2 mg, 23.0 pmol, 0.005 equiv.) and DPEPhos (37 mg, 69.1 pmol, 0.015 equiv.) in 9.2 mL toluene was added sodium tert-butoxide (620 mg, 6.45 mmol, 1.4 equiv.). The resulting solution was purged with N₂ for 5 min before the reaction vessel was sealed and heated at 100° C. for 16 hours before being quenched with 20 mL water and extracted with ethyl acetate (3×20 mL). The combined organic extracts were dried over Na₂SO₄, the volatiles removed in vacuo and the crude product was purified by chromatography on silica gel (50:1 petroleum ether 40-60/ethyl acetate) to give 2-bromo-N-(4-decylphenyl)aniline (1.62 g, 4.17 mmol, 75%) as a pale yellow oil. ¹H NMR (400 MHz, CDCl₃) δ 7.52 (1H, dd, J=7.9, 1.4 Hz), 7.18 (1H, d, J=2.0 Hz), 7.17 (1H, d, J=1.8 Hz), 7.15 (2H, m), 7.08-7.13 (2H, m), 6.68-6.74 (1H, m), 6.05 (1H, s), 2.55-2.64 (2H, m), 1.62 (2H, quin, J=7.4 Hz), 1.20-1.41 (14H, m), 0.86-0.95 (3H, m). ¹³C NMR (125 MHz, CDCl₃) δ 14.2, 22.7, 29.4, 29.4, 29.6, 29.7, 31.7, 31.9, 35.4, 111.5, 115.0, 120.2, 121.2, 128.1, 129.4, 132.9, 137.9, 138.9, 142.1.

### General Method 3

### synthesis of N-(2-bromophenyl)decanamide

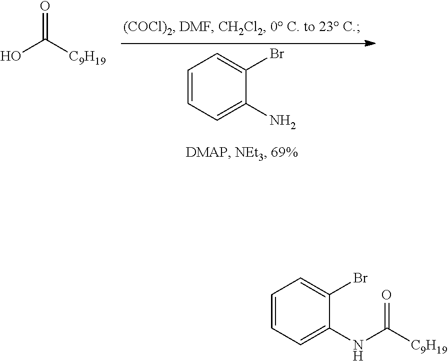

To a solution of decanoic acid (4.13 g, 24 mmol, 1.2 equiv.) and DMF (0.2 mL, 2.58 mmol, 0.11 equiv.) in 20 mL CH₂Cl₂ at 0° C. was added oxalyl chloride (2.03 2.06 mL, 24 mmol, 1.2 equiv.). After stirring at 0° C. for 10 min the reaction was allowed to warm to 23° C. and stirred for a further hour before 2-bromoaniline (3.44 g, 20 mmol, 1 equiv.), DMAP (244 mg, 2 mmol, 0.1 equiv.), NEt₃ (6.69 mL, 48 mmol, 2.4 equiv.) and 20 mL CH₂Cl₂ were added and the reaction was stirred for 16 hours before being quenched with saturated 100 mL NaHCO₃ (aq.) and extracted with ethyl acetate (3×40 mL). The combined organic extracts were dried over Na₂SO₄, the volatiles removed in vacuo and the crude product was purified by chromatography on silica gel (30:1 petroleum ether 40-60/ethyl acetate) to give N-(2-bromophenyl)decanamide (4.56 g, 14.0 mmol, 69 70%) as a colourless solid. ¹H NMR (500 MHz, CDCl₃) δ 8.17 (1H, d, J=7.9 Hz), 7.47 (1H, br. s.), 7.34 (1H, dd, J=8.2, 1.3 Hz), 7.09-7.14 (1H, m), 6.73-6.82 (1H, m), 2.24 (2H, t, J=7.6 Hz), 1.56 (2H, quin, J=7.5 Hz), 1.00-1.28 (12H, m), 0.70 (3H, t, J=6.8 Hz).

### General Method 4

### synthesis of N-(2-bromophenyl)dodecane-1-sulfonamide

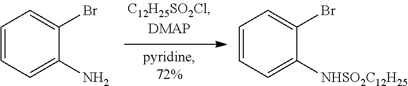

A solution 2-bromoaniline (5.45 g, 31.7 mmol, 1 equiv.), dodecane-1-sulfonyl chloride (10.2 g, 38 mmol, 1.2 equiv.) and DMAP (387 mg, 3.17 mmol, 0.1 equiv.) in 64 mL pyridine was stirred for 72 hours before being quenched with saturated 200 mL NaHCO₃ (aq.) and extracted with ethyl acetate (3×100 mL). The combined organic extracts were dried over Na₂SO₄, the volatiles removed in vacuo and the crude product was purified by chromatography on silica gel (5% ethyl acetate in petroleum ether 40-60) to give N-(2-bromophenyl)dodecane-1-sulfonamide (9.23 g, 22.8 mmol, 72%) as a colourless solid. ¹H NMR (400 MHz, CDCl₃) δ 7.69 (1H, dd, J=8.1, 1.5 Hz), 7.58 (1H, dd, J=8.1, 1.5 Hz), 7.29-7.39 (1H, m), 7.00-7.11 (1H, m), 6.78 (1H, br. s.), 2.98-3.15 (2H, m), 1.74-1.88 (2H, m), 1.16-1.45 (18H, m), 0.82-0.95 (3H, t, J=6.8 Hz).

### General Method 5

### synthesis of N-dodecyl-2-(4,4,5,5-tetramethyl-1,3,2-dioxaborolan-2-yl)aniline

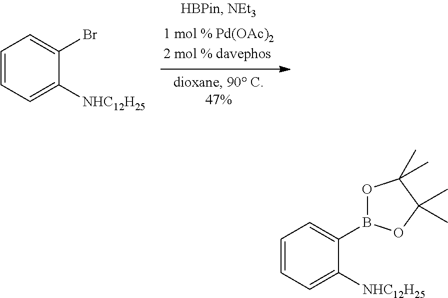

To a solution of palladium acetate (4.5 mg, 20 μmol, 0.001 equiv.), 2′-(dicyclohexylphosphino)-N,N-dimethyl-[1,1′-biphenyl]-2-amine (16 mg, 40 pmol, 0.002 equiv.) and NEt₃ (1.12 mL, 8 mmol, 4 equiv.) in 4 mL dioxane was added 2-bromo-N-dodecylaniline (681 mg, 2 mmol, 1 equiv.). The resulting solution was purged with N₂ for 5 min before 4,4,5,5-tetramethyl-1,3,2-dioxaborolane (0.580 mL, 4 mmol, 2 equiv.) was added over 5 min. The reaction was purged with N₂ for 10 min before the reaction vessel was sealed and heated at 90° C. for 18 hours. Upon cooling to 23° C. the reaction was quenched with 20 mL water and extracted with ethyl acetate (3×20 mL). The combined organic extracts were dried over Na₂SO₄, the volatiles removed in vacuo and the crude product was purified by chromatography on silica gel (3:1 hexane/CHCl₃ to 1:1 hexane CHCl₃) to give N-dodecyl-2-(4,4,5,5-tetramethyl-1,3,2-dioxaborolan-2-yl)aniline (365 mg, 0.942 mmol, 47%) as a yellow oil. ¹H NMR (500 MHz, CDCl₃) δ 7.63 (1H, dd, J=7.4, 1.4 Hz), 7.28-7.33 (1H, m), 6.61 (1H, t, J=7.3 Hz), 6.55 (1H, d, J=8.5 Hz), 5.84 (1H, br. s.), 3.08-3.16 (2H, m), 1.66 (2H, quin, J=7.2 Hz), 1.40-1.48 (2H, m), 1.35 (12H, s), 1.28 (16H, m), 0.90 (3H, t, J=6.9 Hz). ¹³C NMR (125 MHz, CDCl₃) δ 14.1, 22.7, 24.9, 27.2, 29.2, 29.4, 29.5, 29.7, 29.7, 29.7, 31.9, 43.2, 83.4, 109.4, 115.1, 133.1, 137.1, 154.8. Mass spectrum (APCl): m/z ([M+H]) 388

### General Method 6

### synthesis of N-(4-decylphenyl)-2-(4,4,5,5-tetramethyl-1,3,2-dioxaborolan-2-yl)aniline

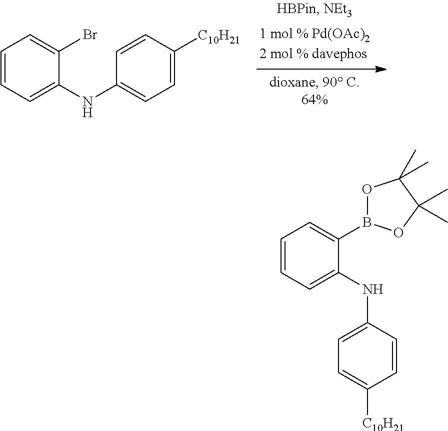

To a solution of palladium acetate (5.4 mg, 24.0 pmol, 0.001 equiv.), 2′-(dicyclohexylphosphino)-N,N-dimethyl-[1,1′-biphenyl]-2-amine (19 mg, 47.9 pmol, 0.002 equiv.) and NEt₃ (1.34 mL, 9.59 mmol, 4 equiv.) in 2.4 mL dioxane was added 2-bromo-N-(4-decylphenyl)aniline (931 mg, 2.40 mmol, 1 equiv.; General method 2 above). The resulting solution was purged with N₂ for 5 min before 4,4,5,5-tetramethyl-1,3,2-dioxaborolane (0.696 mL, 4.79 mmol, 2 equiv.) was added over 5 min. The reaction was purged with N₂ for 10 min before the reaction vessel was sealed and heated at 90° C. for 18 hours. Upon cooling to 23° C. the reaction was quenched with 20 mL water and extracted with ethyl acetate (3×20 mL). The combined organic extracts were dried over Na₂SO₄, the volatiles removed in vacuo and the crude product was purified by chromatography on silica gel (3:1 hexane/CHCl₃ to 1:1 hexane CHCl₃) to give N-(4-decylphenyl)-2-(4,4,5,5-tetramethyl-1,3,2-dioxaborolan-2-yl)aniline (676 mg, 1.55 mmol, 64%) as a green oil. ¹H NMR (300 MHz, CDCl₃) δ 7.73 (1H, dd, J=7.3, 1.5 Hz), 7.68 (1H, br. s.), 7.24-7.32 (1H, m), 7.15 (5H, s), 6.77 (1H, td, J=7.2, 1.0 Hz), 2.54-2.64 (2H, m), 1.55-1.69 (2H, m), 1.37 (12H, s), 1.20-1.35 (14H, m), 0.85-0.95 (3H, t, J=6.4 Hz). ¹³C NMR (125 MHz, CDCl₃) 14.1, 22.7, 24.9, 29.4, 29.4, 29.6, 29.6, 31.7, 31.9, 35.4, 83.8, 112.7, 117.7, 121.2, 129.1, 132.5, 137.0, 137.3, 139.9, 151.1. Mass spectrum (APCl): m/z ([M+H]) 436

### Example 8

### synthesis of bis(dodecyl)-diindolo-thieno[3,2-b]thiophene

### (i) Synthesis of 2,2′-(thieno[3,2-b]thiophene-2,5-diyl)bis(N-dodecylaniline)

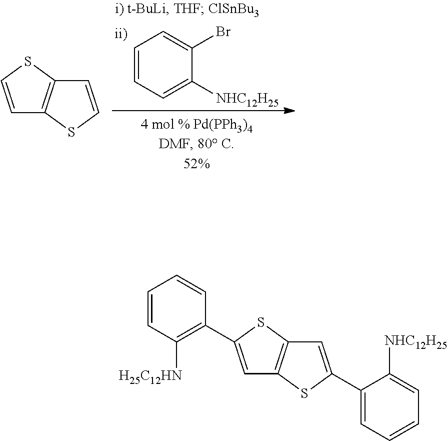

To solution of thieno[3,2-b]thiophene (491 mg, 3.5 mmol, 1 equiv.) in 35 mL THF at −78° C. was added tert-butyllithium (1.52 M in pentane, 5.07 mL, 7.7 mmol, 2.2 equiv.) and the reaction was stirred at 0° C. for 2 hours before being cooled to −78° C. and tributyltin chloride (2.09 mL, 7.7 mmol, 2.2 equiv.) added. The reaction was stirred at 23° C. for 18 hours before being quenched with saturated 50 mL NH₄Cl (aq.) and extracted with pentane (3×50 mL). The combined organic extracts were dried over Na₂SO₄ and the volatiles removed in vacuo to give crude 2,5-bis(tributylstannyl)thieno[3,2-b]thiophene. To this was then added 2-bromo-N-dodecylaniline (2.86 g, 8.4 mmol, 2.4 equiv.; General method 1), Tetrakis(triphenylphosphine) palladium(0) (162 mg, 0.14 mmol, 0.04 equiv.) and 35 mL DMF. The resulting solution was then heated at 80° C. for 24 hours before the crude reaction was passed through a long plug of 10% K₂CO₃/silica eluting with petroleum ether 40-60. The crude product was then purified by precipitation from CH₂Cl₂/MeOH to give 2,2′-(thieno[3,2-b]thiophene-2,5-diyl)bis(N-dodecylaniline) (1.45 g, 2.20 mmol, 62 63%) as a yellow solid. ¹H NMR (500 MHz, CDCl₃) δ 7.34 (2H, s), 7.24-7.32 (4H, m), 6.69-6.79 (4H, m), 4.47 (2H, br. s.), 3.15 (4H, t, J=7.1 Hz), 1.63 (4H, quint, J=7.3 Hz), 1.36-1.44 (4H, m), 1.20-1.34 (32H, m), 0.89 (6H, t, J=6.8 Hz). ¹³C NMR (125 MHz, CDCl₃) δ 14.1, 22.7, 27.2, 29.3, 29.4, 29.4, 29.6, 29.6, 29.7, 29.7, 31.9, 44.0, 110.7, 116.5, 118.5, 119.7, 129.8, 131.2, 139.2 142.5, 146.0. Mass spectrum (MALDI): m/z ([M+H]) 659

### (ii) Synthesis of bis(dodecyl)-diindolo-thieno[3,2-b]thiophene

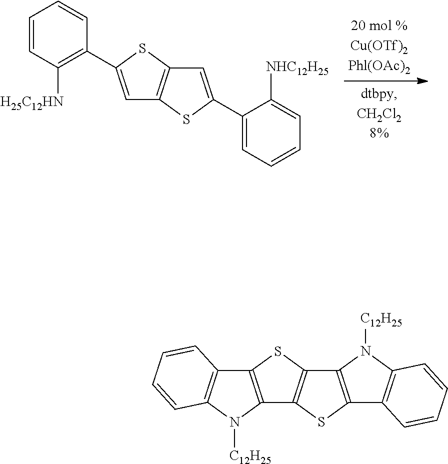

A solution of Phenyliodine diacetate (59 mg, 0.182 mmol, 2.4 equiv.) in 1.5 mL CH₂Cl₂ was added dropwise over 30 min to a stirred solution of 2,2′-(thieno[3,2-b]thiophene-2,5-diyl)bis(N-dodecylaniline) (50 mg, 75.9 pmol, 1 equiv.), Cu(OTf)₂ (5.5 mg, 15.2 pmol, 0.2 equiv.) and 2,6-di-tert-butyl pyridine (40 μL, 0.182 mmol, 2.4 equiv.) in 1.5 mL CH₂Cl₂. After 24 hours the reaction was purified directly by chromatography on silica gel (15:1 to 5:1 hexane/toluene) to give bis(dodecyl)-diindolo-thieno[3,2-b]thiophene (4 mg, 6.11 μmol, 8%) as a yellow solid. ¹H NMR (300 MHz, CDCl₃) δ 7.74 (2H, d, J=7.7 Hz), 7.41-7.49 (2H, d, J=8.1 Hz), 7.32 (2H, dd, J=7.7, 8.1 Hz), 7.18-7.26 (2H, t, J=7.7 Hz), 4.42 (4H, t, J=7.2 Hz), 1.91-2.05 (4H, m), 1.07-1.54 (36H, m), 0.87 (6H, t, J=6.6 Hz). ¹³C NMR (75 MHz, CDCl₃) δ 14.1, 22.7.27.2, 29.3, 29.4, 29.5, 29.6, 29.6, 30.7, 31.9, 46.0, 110.1, 116.3, 118.4, 119.6, 122.3, 122.8, 124.0, 137.7, 140.6. Mass spectrum (MALDI): m/z ([M+H]) 655

### Example 9

### synthesis of bis(dodecylsulfonyl)-diindolo-thieno[3,2-b]thiophene

### (i) Synthesis of N,N′-(thieno[3,2-b]thiophene-2,5-diylbis(2,1-phenylene))bis(dodecane-1-sulfonamide)

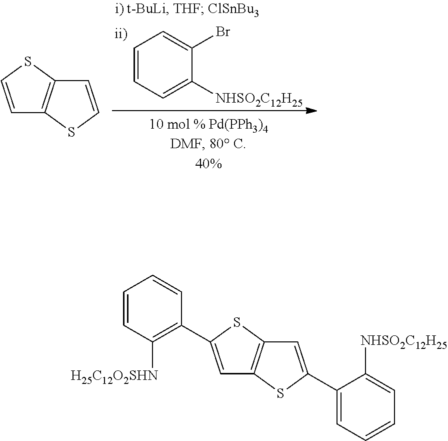

To solution of thieno[3,2-b]thiophene (63 mg, 0.45 mmol, 1 equiv.) in 4.5 mL THF at −78° C. was added tert-butyllithium (1.44 M in pentane, 0.656 mL, 0.944 mmol, 2.1 equiv.) and the reaction was stirred at 0° C. for 2 hours before being cooled to −78° C. and tributyltin chloride (0.256 mL, 0.944 mmol, 2.1 equiv.) added. The reaction was stirred at 23° C. for 18 hours before being quenched with saturated 50 mL NH₄Cl (aq.) and extracted with pentane (3×50 mL). The combined organic extracts were dried over Na₂SO₄ and the volatiles removed in vacuo to give crude 2,5-bis(tributylstannyl)thieno[3,2-b]thiophene. To this was then added N-(2-bromophenyl)dodecane-1-sulfonamide (400 mg, 0.989 mmol, 2.2 equiv.; General method 4), Tetrakis(triphenylphosphine)palladium(0) (52 mg, 45.0 pmol, 0.1 equiv.) and 4.5 mL DMF. The resulting solution was then heated at 80° C. for 24 hours before the crude reaction was passed through a long plug of 10% K₂CO₃/silica eluting with 10-70% ethyl acetate/petroleum ether 40-60 then 10% MeOH/CH₂Cl₂. The crude product was then purified by precipitation from CH₂Cl₂/MeOH to give N,N′-(thieno[3,2-b]thiophene-2,5-diylbis(2,1-phenylene))bis(dodecane-1-sulfonamide) (143 mg, 0.182 mmol, 40%) as a yellow solid. ¹H NMR (400 MHz, CDCl₃) δ 7.67-7.74 (2H, m), 7.41-7.50 (4H, m), 7.33 (2H, s), 7.23 (2H, td, J=7.6, 1.3 Hz), 6.87 (2H, s), 3.09-3.17 (4H, m), 1.69-1.79 (4H, m), 1.15-1.42 (38H, m), 0.83-0.92 (6H, t, J=6.81 Hz). ¹³C NMR (100 MHz, CDCl₃) δ 14.2, 22.7, 23.4, 28.1, 29.0, 29.3, 29.4, 29.5, 29.6, 31.9, 52.3, 119.2, 119.8, 124.4, 124.5, 130.3, 131.8, 135.1, 140.3. Mass spectrum (APCI): m/z ([M+11]) 787

### (ii) Synthesis of bis(dodecylsulfonyl)-diindolo-thieno[3,2-b]thiophene

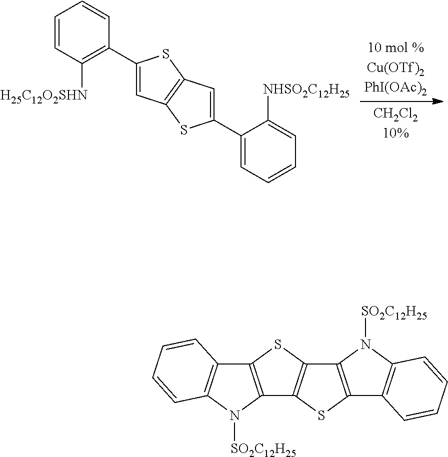

A solution of Phenyliodine diacetate (49 mg, 0.152 mmol, 2.4 equiv.) in 1.25 mL CH₂Cl₂ was added dropwise over 30 min to a stirred solution of N,N′-(thieno[3,2-b]thiophene-2,5-diylbis(2,1-phenylene))bis(dodecane-1-sulfonamide) (50 mg, 63.5 pmol, 1 equiv.) and Cu(OTf)₂ (2.3 mg, 6.35 pmol, 0.1 equiv.) in 1.25 mL CH₂Cl₂. After 24 hours the reaction was purified directly by chromatography on silica gel (5% ethyl acetate/hexane) to give bis(dodecylsulfonyl)-diindolo-thieno[3,2-b]thiophene (5 mg, 6.35 pmol, 10%) as a colourless solid. ¹H NMR (400 MHz, CDCl₃) δ 8.09-8.13 (2H, m), 7.72-7.76 (2H, m), 7.41-7.45 (4H, m), 3.27-3.32 (4H, m), 1.63-1.76 (4H, m), 1.06-1.35 (36H, m), 0.86 (6H, t, J=7.1 Hz). Mass spectrum (APCl): m/z ([M+H]) 783

### Example 10

### synthesis of 5,11-bis(dodecylsulfonyl)-5,11-dihydroindolo[3,2-b]carbazole

### (i) Synthesis of N,N′-([1,1′:4′,1″-terphenyl]-2,2″-diyl)bis(dodecane-1-sulfonamide)

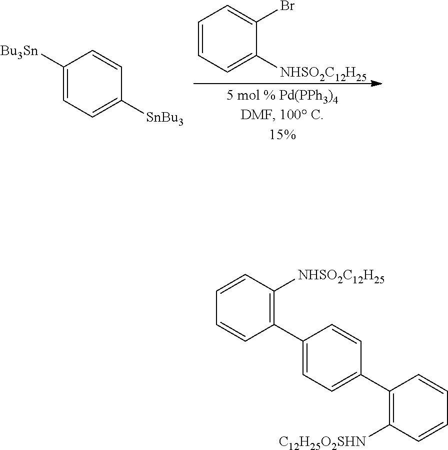

A solution of 1,4-bis(tributylstannyl)benzene (520 mg, 0.792 mmol, 1 equiv.), N-(2-bromophenyl)dodecane-1-sulfonamide (705 mg, 1.74 mmol, 2.2 equiv.; General method 4), Tetrakis(triphenylphosphine)palladium(0) (28 mg, 39.6 μmol, 0.05 equiv.) and 7.92 mL DMF was heat at 100° C. for 48 hours. The reaction was quenched with 20 mL saturated NaHCO₃ (aq.) and extracted with ethyl acetate (3×40 mL). The combined organic extracts were dried over Na₂SO₄, the volatiles removed in vacuo and the crude product was purified by chromatography on silica gel (20:1 to 5:1 hexane/ethyl acetate) to give N,N′-([1,1′:4′,1″-terphenyl]-2,2″-diyl)bis(dodecane-1-sulfonamide) (89 mg, 0.123 mmol, 15%) as a colourless solid. ¹H NMR (300 MHz, CDCl₃) δ 7.59 (2H, d, J=8.3 Hz), 7.41 (4H, s), 7.30-7.37 (2H, m), 7.21-7.28 (2H, m), 7.11-7.20 (2H, m), 6.40 (2H, s), 2.93-3.05 (4H, m), 1.56-1.68 (4H, m), 1.01-1.33 (36H, m), 0.73-0.87 (6H, t, J=6.2 Hz). ¹³C NMR (100 MHz, CDCl₃) δ 14.2, 22.7, 23.4, 28.2, 29.1, 29.3, 29.3, 29.5, 29.6, 31.9, 52.3, 119.2, 124.6, 129.3, 130.2, 130.9, 131.62, 134.2, 137.62. Mass spectrum (AFCl): m/z ([M−H]) 723

### (ii) Synthesis of 5,11-bis(dodecylsulfonyl)-5,11-dihydroindolo[3,2-b]carbazole

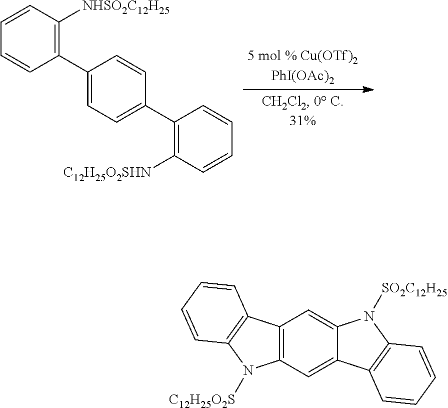

A solution of Phenyliodine diacetate (38 mg, 0.119 mmol, 2.4 equiv.) in 2 mL CH₂Cl₂ was added dropwise over 30 min to a stirred solution of N,N′-([1,1′:4′,1″-terphenyl]-2,2″-diyl)bis(dodecane-1-sulfonamide) (36 mg, 49.6 pmol, 1 equiv.) and Cu(OTf)₂ (0.9 mg, 2.48 pmol, 0.05 equiv.) in 2 mL CH₂Cl₂ at 0° C. After 6 hours the reaction was purified directly by chromatography on silica gel (5% ethyl acetate/hexane) to give 5,11-bis(dodecylsulfonyl)-5,11-dihydroindolo[3,2-b]carbazole (11 mg, 15.4 pmol, 31%) as a colourless solid. ¹H NMR (400 MHz, CDCl₃) δ 8.75 (2H, s), 8.14-8.23 (4H, m), 7.51-7.58 (2H, m), 7.47 (2H, td, J=7.4, 1.0 Hz), 3.19-3.26 (4H, m), 1.62-1.73 (4H, m), 1.06-1.35 (36H, m), 0.87 (6H, t, J=7.1 Hz). ¹³C NMR (100 MHz, CDCl₃) 14.1, 22.7, 28.0, 28.8, 29.1, 29.3, 29.4, 29.5, 29.5, 31.6, 31.9, 52.4, 105.8, 114.7, 120.6, 124.08, 126.05, 126.3, 128.0, 135.9, 139.6. Mass spectrum (APCl): m/z ([M+H]) 721

### Example 11

### Synthesis of 5,11-ditosyl-5,11-dihydroindolo[3,2-b]carbazole

### (i) Synthesis of N,N′-([1,1′:4′,1″-terphenyl]-2,2″-diyl)bis(4-methylbenzene sulfonamide)

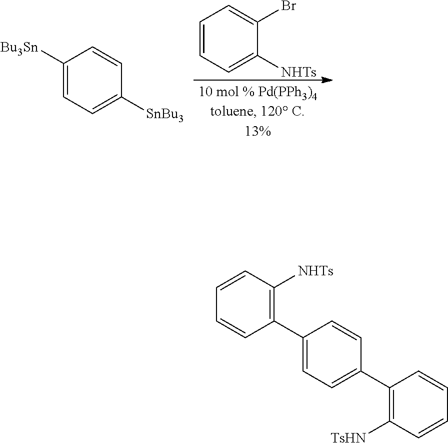

A solution of 1,4-bis(tributylstannyl)benzene (771 mg, 1.17 mmol, 1 equiv.), N-(2-bromophenyl)-4-methylbenzenesulfonamide (920 mg, 2.82 mmol, 2.4 equiv.), Tetrakis(triphenylphosphine)palladium(0) (136 mg, 0.117 mmol, 0.1 equiv.) in 2.34 mL toluene was heat at 120° C. for 72 hours in sealed reaction vessel. The reaction was quenched with 20 mL saturated NaHCO₃ (aq.) and extracted with CHCl₃ (3×40 mL). The combined organic extracts were dried over Na₂SO₄, the volatiles removed in vacuo and the crude product was purified by chromatography on silica gel (CHCl₃) to give N,N′-([1,1′:4′,1″-terphenyl]-2,2″-diyl)bis(4-methylbenzenesulfonamide) (90 mg, 0.158 mmol, 13%) as a colourless solid. ¹H NMR (300 MHz, CDCl₃) δ 7.62 (2H, d, J=7.9 Hz), 7.48 (4H, d, J=8.3 Hz), 7.26-7.35 (2H, m), 7.04-7.18 (8H, m), 6.81 (4H, s), 6.43 (2H, s), 2.34 (6H, s). Mass spectrum (APCl): m/z ([M−H]) 567

### (ii) Synthesis of 5,11-ditosyl-5,11-dihydroindolo[3,2-b]carbazole

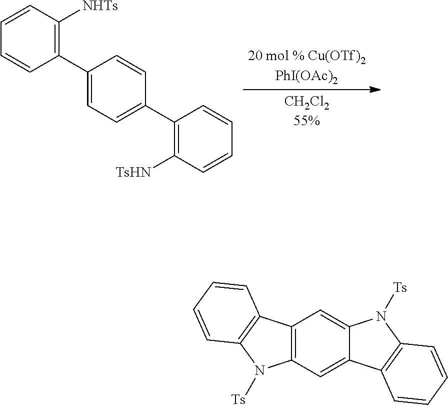

Phenyliodine diacetate (30 mg, 92.8 μmol, 2.4 equiv.) was added as a solid to a stirred solution of N,N′-([1,1′:4′,1″-terphenyl]-2,2″-diyl)bis(4-methylbenzenesulfonamide) (22 mg, 38.7 pmol, 1 equiv.) and Cu(OTf)₂ (2.8 mg, 7.74 pmol, 0.25 equiv.) in 1.6 mL CH₂Cl₂. After 24 hours the reaction was purified directly by chromatography on silica gel (0-2% ethyl acetate in CHCl₃) to give 5,11-ditosyl-5,11-dihydroindolo[3,2-b]carbazole (12 mg, 21.3 pmol, 55%) as a colourless solid. ¹H NMR (400 MHz, CDCl₃) δ 8.83 (2H, s), 8.34 (2H, d, J=8.3 Hz), 8.11 (2H, d, J=8.3 Hz), 7.70 (4H, d, J=8.2 Hz), 7.54 (2H, ddd, J=8.4, 7.3, 1.3 Hz), 7.44 (2H, td, J=7.4, 1.0 Hz), 7.08 (4H, d, J=8.2 Hz), 2.26 (6H, s).

### Example 12

### Synthesis of 1,1′-(indolo[3,2-b]carbazole-5,11-diyl)bis(decan-1-one)

### (i) Synthesis of N,N′-([1,1′:4′,1″-terphenyl]-2,2″-diyl)bis(decanamide)

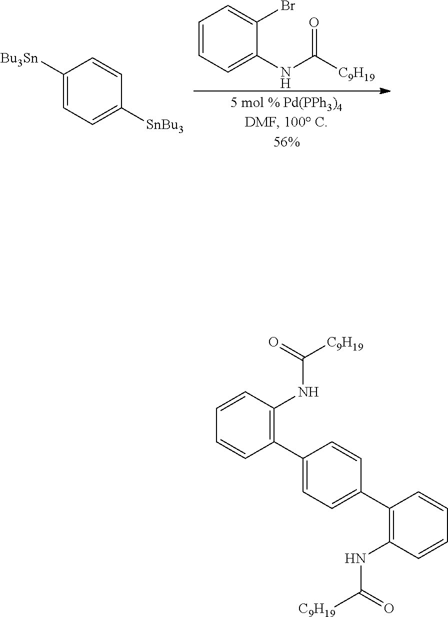

A solution of 1,4-bis(tributylstannyl)benzene (425 mg, 0.648 mmol, 1 equiv.), N-(2-bromophenyl)decanamide (465 mg, 1.42 mmol, 2.2 equiv.; General method 3), Tetrakis(triphenylphosphine)palladium(0) (23 mg, 32.4 pmol, 0.05 equiv.) and 6.5 mL DMF was heat at 100° C. for 48 hours. The reaction was quenched with 20 mL saturated NaHCO₃ (aq.) and extracted with ethyl acetate (3×40 mL). The combined organic extracts were dried over Na₂SO₄, the volatiles removed in vacuo and the crude product was purified by chromatography on silica gel (10-20% ethyl acetate/hexane) to give crude N,N′-([1,1′:4′,1″-terphenyl]-2,2″-diyl)bis(decanamide) (182 mg) that was purified by precipitation from CH₂Cl₂/MeOH to give N,N′-([1,1′:4′,1″-terphenyl]-2,2″-diyl)bis(decanamide) (136 mg, 0.239 mmol, 56%) as a colourless solid. ¹H NMR (400 MHz, CDCl₃) δ 8.29 (2H, d, J=8.1 Hz), 7.52 (4H, s), 7.38-7.46 (2H, m), 7.31 (2H, d, J=6.6 Hz), 7.20-7.26 (2H, m), 7.16 (2H, br. s.), 2.25 (4H, t, J=7.6 Hz), 1.60-1.69 (4H, m), 1.18-1.37 (24H, m), 0.83-0.89 (6H, m). Mass spectrum (APCl): m/z ([M−H]) 567

### (ii) Synthesis of 1,1′-indolo[3,2-b]carbazole-5,11-diyl)bis(decan-1-one)

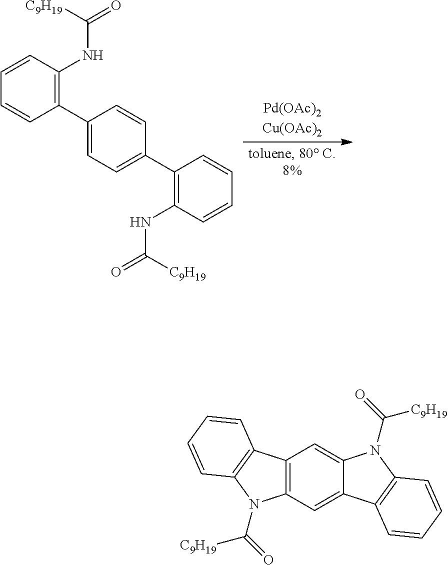

A solution of N,N′-([1,1′:4′,1″-terphenyl]-2,2″-diyl)bis(decanamide) (60 mg, 0.105 mmol, 1 equiv.), palladium acetate (5 mg, 21.1 pmol, 0.2 equiv.) and copper(II) acetate (57 mg, 0.316 mmol, 3 equiv.) in 2 mL toluene was heated for 24 hours at 80° C. in air. Upon cooling the products were purified by chromatography on silica gel (5% ethyl acetate/hexane) to give ,1′-(indolo[3,2-b]carbazole-5,11-diyl)bis(decan-1-one) (5 mg, 8.85 μmol, 8%) as a colourless solid. ¹H NMR (400 MHz, CDCl₃) δ 8.90 (2H, s), 8.03 (2H, dd, J=7.6, 0.8 Hz), 7.95 (2H, d, J=8.3 Hz), 7.40-7.45 (2H, m), 7.31-7.37 (2H, m), 3.10 (4H, t, J=7.4 Hz), 1.90 (4H, quin, J=7.4 Hz), 1.42-1.58 (4H, m), 1.08-1.40 (20H, m), 0.78-0.85 (6H, m). Mass spectrum (APCl): m/z ([M+H]) 565

### Example 13

### Synthesis of 5,12-didodecyl-5,12-dihydrocarbazolo[3,2-b]carbazole

### (i) Synthesis of 2,6-bis(tributylstannyl)naphthalene

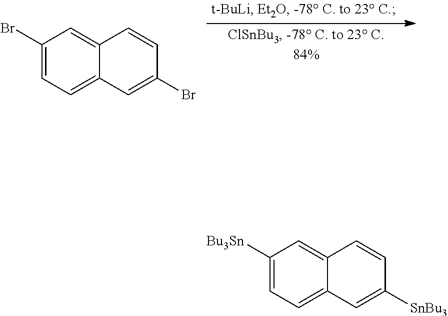

To a suspension of 2,6-dibromonaphthalene (2.526 g, 8.83 mmol, 1 equiv.) in 88 mL diethyl ether at −78° C. was added tert-butyl lithium (1.605 M in pentane, 22.0 mL, 35.3 mmol, 4 equiv.) and the resulting suspension was allowed to stir at 23° C. for 18 hours. After 18 hours the reaction was cooled to −78° C. and tributyltin chloride (5.03 mL, 18.5 mmol, 2.1 equiv.) was added and the reaction was stirred at 23° C. for a further 5 hours before being quenched with saturated 100 mL NH₄Cl (aq.) and extracted with hexane (3×100 mL). The combined organic extracts were dried over Na₂SO₄, volatiles removed in vacuo and the crude products were purified by chromatography on 10% K₂CO₃/silica (petroleum ether 40-60) to give 2,6-bis(tributylstannyl)naphthalene (5.31 g, 7.52 mmol, 84%) as a colourless oil. ¹H NMR (300 MHz, CDCl₃) δ 7.92 (2H, s), 7.77 (2H, d, J=7.9 Hz), 7.57 (2H, d, J=7.9 Hz), 1.46-1.73 (12H, m), 1.24-1.45 (12H, m), 1.02-1.22 (12H, m), 0.81-0.99 (18H, m).

### (ii) Synthesis of 2,7-(naphthalene-2,6-diyl)bis(N-dodecylaniline)

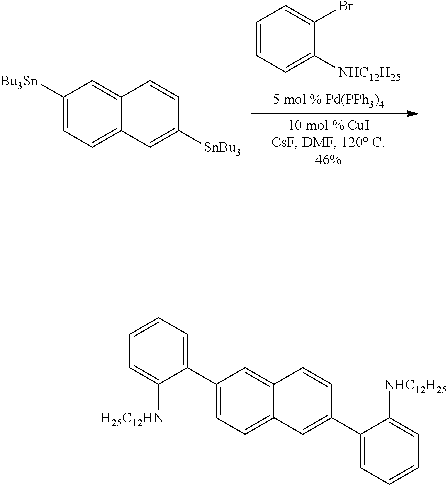

A solution of 2,6-bis(tributylstannyl)naphthalene (1.41 m, 2 mmol, 1 equiv.), 2-bromo-N-dodecylaniline (1.63 g, 4.8 mmol, 2.4 equiv.; General method 1), Tetrakis(triphenylphosphine)palladium(0) (116 mg, 0.1 mmol, 0.05 equiv.), CuI (38 mg, 0.2 mmol, 0.1 equiv.) and CsF (1.22 g, 8 mmol, 4 equiv.) in 12 mL DMF was heat at 120° C. for 72 hours. The reaction was quenched with 20 mL water and 20 mL CH₂Cl₂ was added before the reaction was filtered through celite and solids were washed with ethyl acetate (5×20 mL) and water (5×20 mL) and the washings were combined and extracted with ethyl acetate (3×50 mL). The combined organic extracts were dried over Na₂SO₄, volatiles removed in vacuo and the crude products were purified by chromatography on 10% K₂CO₃/silica (1:0 to 50:1 petroleum ether 40-60/ethyl acetate) to give crude 2,2′-(naphthalene-2,6-diyl)bis(N-dodecylaniline) (1.15 g) the was then purified by precipitation from CHCl₃/MeOH to give pure 2,2′-(naphthalene-2,6-diyl)bis(N-dodecylaniline) (595 mg, 0.929 mmol, 46%) and a colourless solid. ¹H NMR (300 MHz, CDCl₃) δ 7.89-7.99 (4H, m), 7.62 (2H, dd, J=8.5, 1.1 Hz), 7.28-7.35 (2H, m), 7.22 (2H, dd, J=7.5, 1.5 Hz), 6.83 (2H, t, J=7.4 Hz), 6.78 (2H, d, J=8.1 Hz), 4.00 (2H, br. s.), 3.14 (4H, t, J=7.1 Hz), 1.47-1.64 (4H, m), 1.27 (36H, s), 0.83-0.95 (6H, m). ¹³C NMR (75 MHz, CDCl₃) δ 14.1, 22.7, 27.2, 29.4, 29.6, 29.7, 29.7, 31.9, 44.1, 110.5, 116.8, 127.2, 128.0, 128.1, 128.5, 128.9, 130.4, 132.8, 137.4, 145.5 Mass spectrum (APCl): m/z ([M+H]) 647

### (iii) Synthesis of 5,12-didodecyl-5,12-dihydrocarbazolo[3,2-b]carbazole

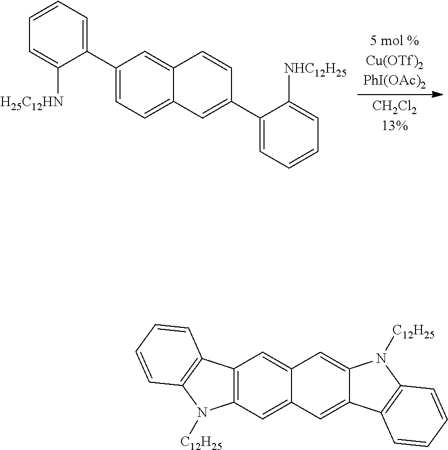

A solution of Phenyliodine diacetate (195 mg, 0.607 mmol, 4 equiv.) in 3 mL CH₂Cl₂ was added dropwise over 10 min to a stirred solution of 2,2′-(naphthalene-2,6-diyl)bis(N-dodecylaniline) (100 mg, 0.152 mmol, 1 equiv.) and Cu(OTf)₂ (5.5 mg, 15.2 μmol, 0.1 equiv.) in 3 mL CH₂Cl₂. After 4 hours the reaction was filtered through a plug of silica and the products purified by chromatography on silica gel (15:1 to 5:1 hexane/toluene) to give 5,12-didodecyl-5,12-dihydrocarbazolo[3,2-b]carbazole (13 mg, 20.2 pmol, 13%) as colourless solid. ¹H NMR (400 MHz, CDCl₃) δ 8.41 (2H, d, J=8.8 Hz), 8.33 (2H, d, J=8.6 Hz), 8.21 (2H, d, J=7.6 Hz), 7.60 (2H, d, J=8.36 Hz), 7.53 (3H, td, J=7.6, 1.1 Hz), 7.31-7.38 (2H, m), 4.80-4.89 (4H, m), 2.17 (4H, quin, J=7.8 Hz), 1.53-1.65 (8H, m), 1.41-1.50 (4H, m), 1.23-1.39 (24H, m), 0.89 (6H, t, J=6.8 Hz). ¹³C NMR (100 MHz, CDCl₃) δ 14.2, 22.7, 27.1, 29.4, 29.4, 29.6, 29.7, 30.2, 31.9, 46.6, 109.3, 114.1, 118.3, 118.7, 119.5, 119.6, 121.5, 123.0, 124.9, 136.3, 141.0. Mass spectrum (APCl): m/z ([M+H]) 643

### Example 14

### Synthesis of 5,12-bis(dodecylsulfonyl)-5,12-dihydrocarbazolo[3,2-b]carbazole

### (i) Synthesis of N,N′-(naphthalene-2,6-diyl)bis(2,1-phenylene))bis(dodecane-1-sulfonamide)

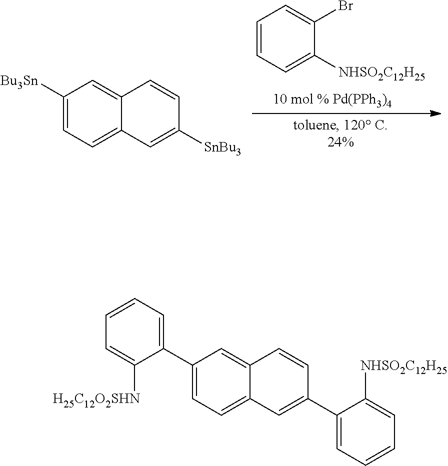

A solution of 2,6-bis(tributylstannyl)naphthalene (915 mg, 1.30 mmol, 1 equiv.; Example 13), N-(2-bromophenyl)dodecane-1-sulfonamide (1.26 g, 3.11 mmol, 2.4 equiv.; General method 4), Tetrakis(triphenylphosphine)palladium(0) (150 mg, 0.130 mmol, 0.1 equiv.) in 2.6 mL toluene was heated at 120° C. for 72 hours in sealed reaction vessel. The reaction was quenched with 20 mL saturated NaHCO₃ (aq.) and extracted with CHCl₃ (3×40 mL). The combined organic extracts were dried over Na₂SO₄, the volatiles removed in vacuo and the crude product was purified by chromatography on silica gel (CHCl₃) to give N,N′-(naphthalene-2,6-diylbis(2,1-phenylene))bis(4-methylbenzenesulfonamide) (244 mg, 0.315 mmol, 24%) as a colourless solid. ¹H NMR (300 MHz, CDCl₃) δ 8.02 (2H, d, J=8.5 Hz), 7.90 (2H, s), 7.72 (2H, d, J=8.1 Hz), 7.54 (2H, d, J=8.3 Hz), 7.41-7.48 (2H, m), 7.34-7.40 (2H, m), 7.23-7.31 (4H, m), 6.50 (2H, s), 2.95-3.07 (4H, m), 1.53-1.67 (4H, m), 1.10-1.38 (36H, m), 0.88 (6H, t, J=7.0 Hz). ¹³C NMR (75 MHz, CDCl₃) δ 14.1, 22.7, 23.4, 28.1, 29.0, 29.2, 29.3, 29.5, 29.6, 31.9, 52.2, 119.6, 124.7, 127.8, 128.2, 129.3, 129.5, 131.0, 132.3, 132.9, 134.4, 135.9. Mass spectrum (APCl): m/z ([M−H]) 773

### (ii) Synthesis of 5,12-bis(dodecylsulfonyl)-5,12-dihydrocarbazolo[3,2-b]carbazole

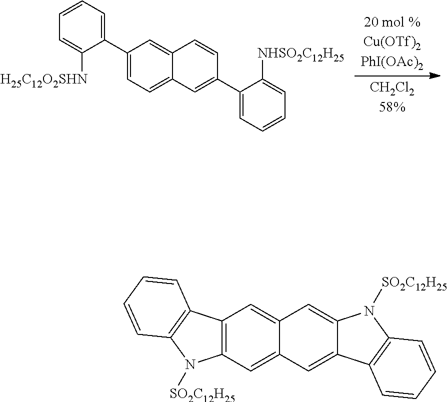

A solution of Phenyliodine diacetate (223 mg, 0.693 mmol, 3 equiv.) was added as a solid to a solution of N,N′-(naphthalene-2,6-diylbis(2,1-phenylene))bis(4-methylbenzenesulfonamide) (179 mg, 0.231 mmol, 1 equiv.) and Cu(OTf)₂ (17 mg, 46.2 μmol, 0.1 equiv.) in 9 mL CH₂Cl₂. After 4 hours the reaction was purified by chromatography on silica gel (5% ethyl acetate/hexane) to give 5,12-bis(dodecylsulfonyl)-5,12-dihydrocarbazolo[3,2-b]carbazole (104 mg, 0.135 mmol, 58%) as colourless solid. ¹H NMR (300 MHz, CDCl₃) δ 8.89 (2H, d, J=8.9 Hz), 8.18-8.30 (2H, m), 8.08 (2H, d, J=8.9 Hz), 8.01-8.05 (2H, m), 7.49-7.59 (4H, m), 2.39-2.51 (4H, m), 1.36-1.52 (4H, m), 0.94-1.32 (36H, m), 0.86 (6H, t, J=6.8 Hz). ¹³C NMR (100 MHz, CDCl₃) δ 14.1, 22.4, 22.7, 27.9, 28.8, 29.0, 29.3, 29.4, 29.5, 29.6, 31.9, 48.7, 117.6, 118.5, 120.2, 125.9, 126.7, 127.5, 129.3, 136.7, 141.6. Mass spectrum (APCl): m/z ([M+Na]) 793

### Example 15

### Synthesis of 5,13-bis(4-decylphenyl)-7,15-diphenyl-5,13-dihydrobenzo[1,2-b:4,5-b′]dicarbazole

### (i) Synthesis of 2,2′-(9,10-diphenylanthracene-2,6-diyl)bis(N-(4-decylphenyl)aniline)

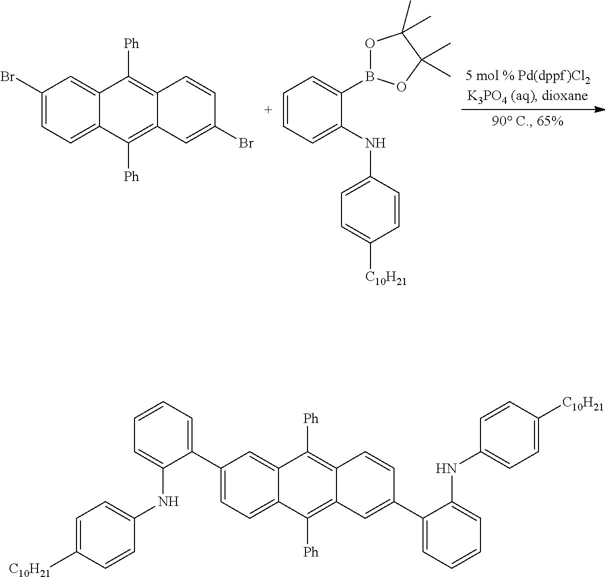

To a degassed solution of 2,6-dibromo-9,10-diphenylanthracene (98 mg, 0.201 mmol, 1 equiv.), N-(4-decylphenyl)-2-(4,4,5,5-tetramethyl-1,3,2-dioxaborolan-2-yl)aniline (245 mg, 0.562 mmol; General method 6), [1,1′-Bis(diphenylphosphino)ferrocene]dichloropalladium(II) (7 mg, 10.0 pmol, 0.05 equiv.) and tripotassium phosphate (341 mg, 1.61 mmol, 8 equiv.) in 2 mL dioxane was added 0.4 mL water. The reaction vessel was then sealed and heated at 90° C. for 48 h before being quenched with 50 mL water and extracted with ethyl acetate (3×20 mL). The combined organic extracts were dried over Na₂SO₄, the volatiles removed in vacuo and the crude product was purified by chromatography on silica gel (10:1 to 3:1 hexane/toluene) to give 2,2′-(9,10-diphenylanthracene-2,6-diyl)bis(N-(4-decylphenyl)aniline) (124 mg, 0.131 mmol, 65%) as a yellow solid. ¹H NMR (400 MHz, CDCl₃) d ppm 7.74 (2H, d, J=1.0 Hz), 7.64-7.71 (2H, m), 7.33-7.42 (12H, m), 7.19-7.23 (2H, m), 7.14-7.19 (2H, m), 7.09-7.13 (2H, m), 6.98 (4H, d, J=8.6 Hz), 6.77-6.90 (6H, m), 5.58 (2H, s), 2.40-2.53 (4H, m), 1.47-1.59 (4H, m), 1.10-1.32 (28H, m), 0.75-0.86 (6H, m). ¹³C NMR (100 MHz, CDCl₃) δ 14.2, 22.7, 29.4, 29.6, 29.7, 31.8, 31.9, 35.3, 116.5, 119.1, 120.4, 126.9, 127.2, 127.6, 127.8, 128.4, 128.5, 129.2, 129.3, 130.2, 130.6, 130.9, 313.2, 135.8, 136.3, 137.3, 138.5, 140.5, 141.1. Mass spectrum (APCl): m/z ([M+H]) 945

### (ii) Synthesis of 5,13-bis(4-decylphenyl)-7,15-diphenyl-5,13-dihydrobenzo[1,2-b:4,5-b′]dicarbazole

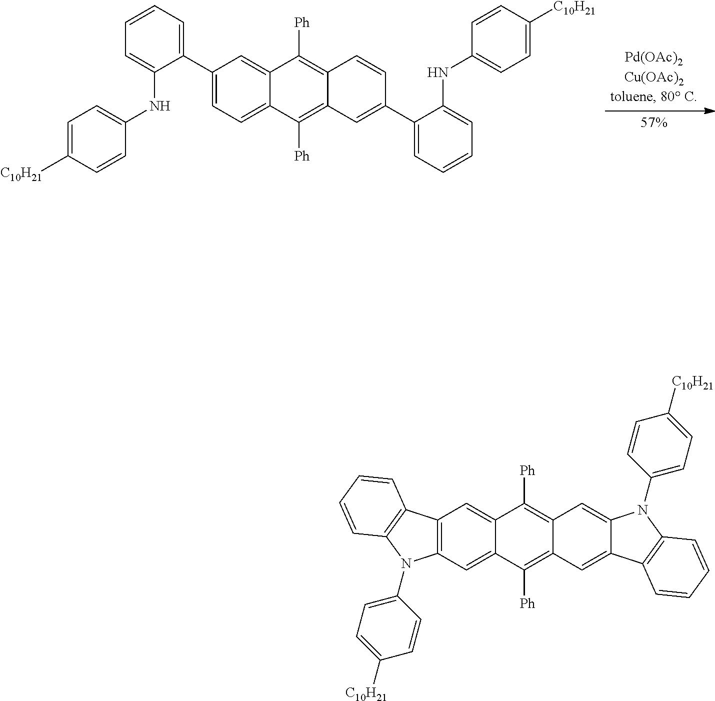

A solution of 2,2′-(9,10-diphenylanthracene-2,6-diyl)bis(N-(4-decylphenyl)aniline) (46 mg, 48.7 μmol, 1 equiv.), palladium acetate (11 mg, 48.7 pmol, 1 equiv.) and copper(II) acetate (27 mg, 0.146 mmol, 3 equiv.) in 2 mL toluene was heated for 24 hours at 80° C. in air. Upon cooling the products were purified by chromatography on amunia (1:0 to 3:1 hexane/toluene) to give crude 5,13-bis(4-decylphenyl)-7,15-diphenyl-5,13-dihydrobenzo[1,2-b:4,5-b′]dicarbazole (45 mg) as a red solid. Precipitation from CH₂C₂/MeOH gave 5,13-bis(4-decylphenyl)-7,15-diphenyl-5,13-dihydrobenzo[1,2-b:4,5-b′]dicarbazole (26 mg, 27.6 μmol, 57%) as a yellow solid. ¹H NMR (500 MHz, C₆D₆) δ 8.24 (2H, s), 8.00-8.05 (4H, m), 7.68 (2H, d, J=7.9 Hz), 7.63 (2H, s), 7.30-7.36 (6H, m), 7.20-7.28 (4H, m), 7.05-7.11 (6H, m), 6.95-7.01 (4H, m), 2.46 (4H, t, J=7.7 Hz), 1.51-1.61 (4H, m), 1.35 (28H, br. s.), 0.95 (6H, t, J=7.25 Hz). Mass spectrum (APCl): m/z ([M+H]) 941

### Example 16

### Synthesis of Poly(dodecylindolocarbazole)

### (i) Synthesis of poly(ortho-N-dodecylaniline-paraphenylene)

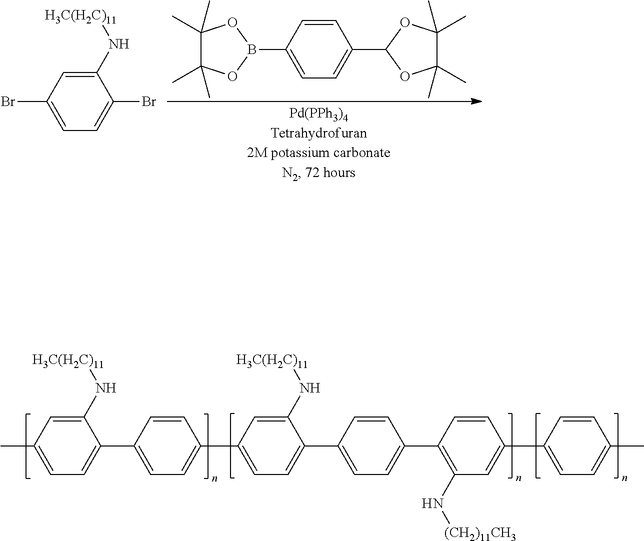

2,5-Dibromo-N-dodecylaniline (127 mg, 0.30 mmol), 1,4-benzenediboronic acid bis(pinacol) ester (100 mg, 0.30 mmol) and palladium tetrakis(triphenylphosphine) (Pd(PPh₃)₄) (14 mg, 0.012 mmol, 2%) where added to a round bottom flask, under a nitrogen atmosphere. Degassed tetrahydrofuran (4 ml) was added followed by degassed 2 M aqueous potassium carbonate (2 ml) and the reaction was then heated to 80 C. After 24 hours additional degassed tetrahydrofuran (2 ml) was added. After 70 hours the viscous solution was cooled to room temperature and precipitated into a large excess of methanol. The precipitate was then filtered and washed with water followed by methanol, leaving a yellow powder (79 mg, 78%). ¹H NMR, (CDCl₃, 300 MHz), δ ppm: 0.75-1.73 (23H, m, Alkyl), 3.23 (2H, m, CH₂N), 4.14 (1H, bs, N—H), 6.87-7.82 (7H, m, Ar—H). GPC (THF): Mₙ=5,300; M_{W}/Mₙ=5.6

(ii) Synthesis of Poly(dodecylindolocarbazole)

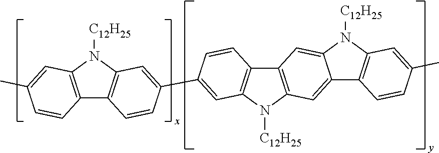

Poly(ortho-N-dodecylaniline-paraphenylene) (100 mg) and Pd(OAc)₂ (3.3 mg, 10 mol %) were stirred, unless otherwise stated, in toluene (0.05 M) at room temperature for 1 h. Phenyliodonium diacetate (PIDA, 114 mg, 0.37 mmol) was then added and the reaction mixture was stirred at room temperature overnight. The mixture was concentrated under reduced pressure. The crude product was precipitated in methanol and then purified by filtration through silica gel (chloroform) to afford the title compound (56 mg) as a pale yellow solid.

### Example 17

### Synthesis of Poly(dodecylcarbazole-didodecylindolocarbazole-paraphenylene)

### (i) Synthesis of Poly(ortho-N-dodecylaniline-paraphenylene)

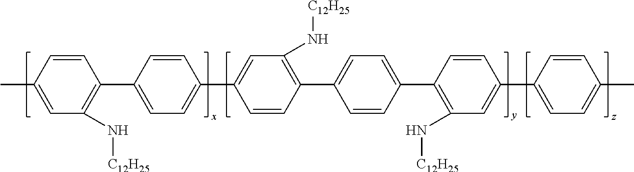

2,5-Dibromo-N-dodecylaniline (127 mg, 0.30 mmol), 1,4-bis(4,4,5,5-tetramethyl-1,3,2-dioxaborolan-2-yl)benzene (100 mg, 0.30 mmol) and Pd(PPh₃)₄ (14 mg, 0.012 mmol, 2% mol) were added to a shlenk tube under an argon atmosphere. Tetrahydrofuran (6 mL) and 2 M aqueous potassium carbonate (2 mL) were added and then degassed. The mixture was heated at 80° C. for 3 days under an argon atmosphere. The mixture was cooled to room temperature and precipitated into methanol. The precipitate was then filtered and extracted with a Soxhlet apparatus (tetrahydrofuran) to afford a white powder (79 mg, 78%). ¹H NMR (CDCl₃) δ 7.82-6.87 (7H, m, Ar—H), 4.14 (1H, bs, N—H), 3.23 (2H, m, CH₂N), 1.73-0.75 (23H, m, Alkyl). GPC (THF): Mₙ=5300; M_{w}/Mₙ=5.6.

### (ii) Synthesis of Poly(dodecylcarbazole-didodecylindolocarbazole-paraphenylene)

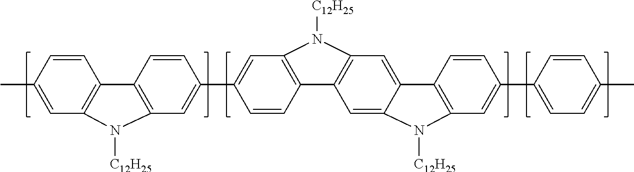

Polydodecylbiphenylamine (50 mg) and Pd(OAc)₂ (3.3 mg, 10 mol %) were stirred, unless otherwise stated, in dichloromethane (0.05 M) at room temperature for 1 h. Phenyliodonium diacetate (PIDA, 114 mg, 0.37 mmol) was then added and the reaction mixture was stirred at room temperature overnight. The mixture was washed with a solution of sodium diethyldithiocarbamate and the organic fraction was concentrated under reduced pressure. The crude was precipitated into methanol. The precipitate was then filtered to afford the title polymer (38 mg, 76%) as a yellow solid.

1. A process for preparing a compound comprising one or more moieties of formula (I): 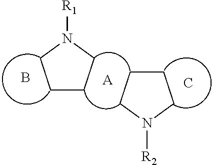
wherein:
R₁ and R₂ are substituent groups; and
Ring A, Ring B and Ring C are π-conjugated ring systems which are optionally substituted;
said process comprising reacting a compound of comprising one or more moieties of formula A1, A3 and/or A4: 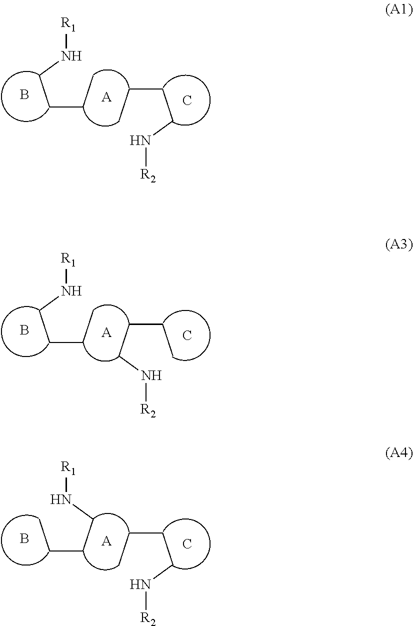
wherein Ring A, Ring B, Ring C, R₁ and R₂ are as defined above;
with an oxidant in the presence of a transition metal catalyst or a salt thereof.

2. A process according to claim 1, wherein said compounds is a compound of formula I.

3. A process according to claim 1, wherein said compound comprising one or more moieties of formula I is a polymer comprising one or more monomeric components of formula II: 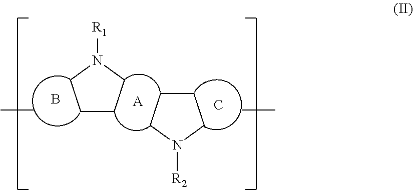
wherein Ring A, Ring B, Ring C, R₁ and R₂ are as defined in claim 1;
and wherein said compounds comprising moieties of formula A1, A3 and/or A4 are polymers comprising monomers of formulae B1, B3 and/or B4: 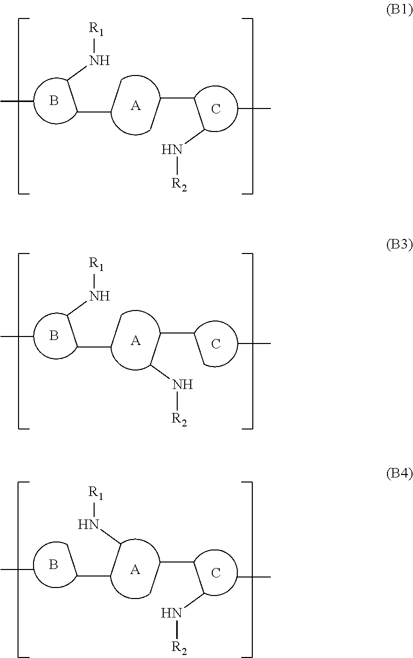
wherein Ring A, Ring B, Ring C, R₁ and R₂ are as defined in claim 1.

4. A process according to claim 1, wherein said compound comprising a moiety of formula I is a polymer which comprises monomers of formula III: 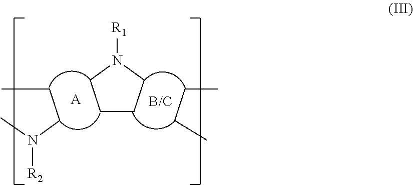
wherein R₁, R₂, Ring A and Ring B/C is a Ring B or C as defined in claim 1;
and wherein said polymer is formed by reacting a polymer comprising monomeric components of formulae C3 and/or C4: 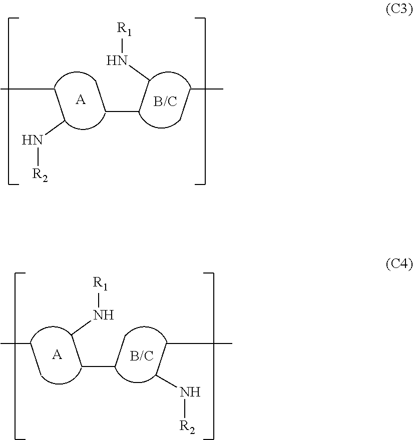
wherein Ring A, Ring B, R₁ and R₂ are as defined in claim 1;
with an oxidant in the presence of a transition metal catalyst or a salt thereof.

5. A process according to claim 1, wherein R₁ and R₂ are each independently selected from (1-20C)alkyl, (2-20C)alkenyl, (2-20C)alkynyl, (2-20C)alkanoyl, (1-20C)alkyl-SO₂—; or a group
-Z¹-Q¹
wherein Z¹ is a direct bond, —CO— or —SO₂—; and
Q¹ is selected from aryl, heteroaryl, heterocyclyl, (3-8C)cycloalkyl, aryl-(1-10C)alkyl, heteroaryl-(1-10C)alkyl, heterocyclyl-(1-10C)alkyl, or (3-8C)cycloalkyl-(1-10C)alkyl; and
wherein Q¹ is optionally substituted with one or more halo, nitro, cyano, hydroxy, (1-20C)alkyl, (2-20C)alkenyl, (2-20C)alkynyl or (2-20C)alkanoyl groups;
and wherein a R₁ or R₂ substituent group is optionally further substituted by one or more substituents R^{a};
and each R^{a} group present is independently selected from halo, nitro, cyano, hydroxy, (1-20C)alkyl, (1-10C)fluoroalkyl (1-10C)fluoroalkoxy amino, carboxy, carbamoyl, mercapto, sulfonylamino, (1-10C)alkoxy, (2-10C)alkanoyl, (1-10C)alkanoyloxy , a cross-linking moiety or a polymerisable group.

6. A process according to claim 5, wherein Ring A, Ring B and Ring C are π-conjugated ring systems that are optionally substituted by one or more R^{b} groups as defined herein, and wherein each R^{b} group present is independently selected from halo, nitro, cyano, hydroxy, (1-20C)alkyl, (1-10C)fluoroalkyl, (1-10C)fluoroalkoxy, amino, carboxy, carbamoyl, mercapto, sulfonylamino, (1-10C)alkoxy, (2-10C)alkanoyl, (1-10C)alkanoyloxy , a cross-linking moiety or a polymerisable group; aryl, heteroaryl, heterocyclyl, or (3-8C)cycloalkyl, aryl-(1-10C)alkyl, heteroaryl-(1-10C)alkyl, heterocyclyl-(1-10C)alkyl, or (3-8C)cycloalkyl-(1-10C)alkyl; and wherein any aryl, heteroaryl, heterocyclyl, or (3-8C)cycloalkyl moiety within a R^{b} substituent groups is optionally substituted with one or more halo, nitro, cyano, hydroxy, (1-20C)alkyl, (2-20C)alkenyl, (2-20C)alkynyl or (2-20C)alkanoyl groups.

7. A process according to claim 1, wherein Ring B and Ring C are the same.

8. A process according to claim 1, wherein R₁ and R₂ are the same.

9. A process according to claim 1, wherein the oxidant is selected from a copper salt, O₂, phenyliodium diacetate (PIDA), or DMSO.

10. A process according to claim 1, wherein the transition metal catalyst is selected from palladium, nickel, platinum, iron, ruthenium, gold, iridium, silver, cobalt, rhodium, mercury, or copper or a salt thereof.

11. A compound of formula (I) 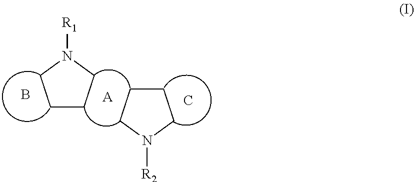
wherein:
R₁ and R₂ are each as defined in claim 6;
Ring A, Ring B and Ring C are conjugated ring systems as defined in claim 6; with the proviso that:
wherein Ring A, Ring B, and Ring C are not all phenyl;
(ii) Ring B and Ring C are not both phenyl when Ring A is a group of formula: 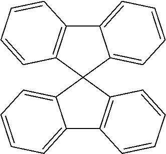 [SMILES: c1ccc2c(c1)-c1ccccc1C21c2ccccc2-c2ccccc21]
(iii) Ring A is not phenyl when both Ring B and Ring C have the formula: 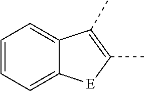
wherein E is selected from S, Se, O or NR₉ (wherein R₉ is hydrogen or (1-20C)alkyl); and
(iv) Ring A is not naphthyl.

12. A compound according to claim 11, wherein R₁ and R₂ are not both alkyl.

13. A compound according to claim 11, wherein Ring B and Ring C are the same and R₁ and R₂ are the same.

14. A compound according to claim 11, wherein R₁ and R₂ are selected from (2-20C)alkanoyl, (1-20C)alkyl-SO₂—; or a group
-Z¹-Q¹
wherein Z¹ is —CO— or —SO₂—; and
Q¹ is selected from aryl, heteroaryl, heterocyclyl, (3-8C)cycloalkyl, aryl-(1-10C)alkyl, heteroaryl-(1-10C)alkyl, heterocyclyl-(1-10C)alkyl, or (3-8C)cycloalkyl-(1-10C)alkyl; and
wherein Q¹ is optionally substituted with one or more (1-20C)alkyl, (2-20C)alkenyl, (2-20C)alkynyl or (2-20C)alkanoyl groups;
and wherein a R₁ or R₂ substituent group is optionally further substituted by one or more substituents R^{a} as defined herein.

15. A polymer comprising one or more monomeric components of formula II: 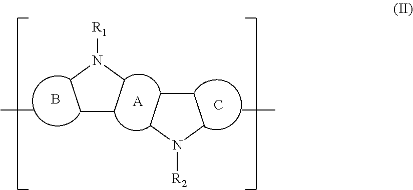
wherein Ring A, Ring B, Ring C are conjugated ring systems as defined in claim 6 and R₁ and R₂ are as defined in claim 6; and subject to the proviso that Rings A, B, and C are not all phenyl and R₁ and R₂ are not both alkyl.

16. A polymer according to claim 15, wherein R₁ and R₂ are selected from (2-20C)alkanoyl, (1-20C)alkyl-SO₂—; or a group
-Z¹-Q¹
wherein Z¹ is —CO— or —SO₂—; and
Q¹ is selected from aryl, heteroaryl, heterocyclyl, (3-8C)cycloalkyl, aryl-(1-10C)alkyl, heteroaryl-(1-10C)alkyl, heterocyclyl-(1-10C)alkyl, or (3-8C)cycloalkyl-(1-10C)alkyl; and
wherein Q¹ is optionally substituted with one or more (1-20C)alkyl, (2-20C)alkenyl, (2-20C)alkynyl or (2-20C)alkanoyl groups;
and wherein a R₁ or R₂ substituent group is optionally further substituted by one or more substituents R^{a} as defined herein.

17. A polymer comprising monomers of formula III 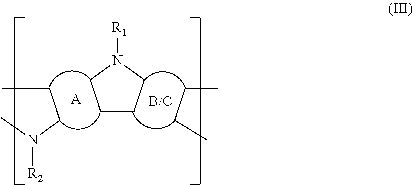
wherein R₁ and R₂ are as defined in claim 5; and Ring A is as defined in claim 6 and Ring B/C is a Ring B or C as defined in claim 6.

18. Use of a compound according to claim 11 material for organic semi-conductor applications.

19. A formulation comprising one or more compounds oligomers of formula I as defined in claim 11, one or more solvents and optionally one or more binders, preferably organic binders, or precursors thereof.

20. A formulation comprising one or more compounds of formula I as defined in claim 11, one or more binders, preferably organic binders, or precursors thereof, and optionally one or more solvents.

21. An organic semiconductor layer comprising one or more compounds of formula I as defined in claim 11.

22. A process for preparing an organic semiconductor layer according to claim 21, comprising the steps of;
depositing on a substrate a liquid layer of a formulation as defined herein;
(ii) forming from the liquid layer a solid layer which forms the organic semiconductor layer; and
(iii) optionally removing the layer form the substrate.

23. An electronic, optical or electro-optical component or device comprising compounds of formula I as defined in claim 11.

24. Use of a polymer as claimed in claim 15 as material for organic semi-conductor applications.

25. A formulation comprising one or more polymers comprising monomeric components of formula II as defined in claim 15, one or more solvents and optionally one or more binders, preferably organic binders, or precursors thereof.

26. A formulation comprising one or more polymers comprising monomeric components of formula III as defined in claim 17, one or more solvents and optionally one or more binders, preferably organic binders, or precursors thereof.

27. A formulation comprising one or more polymers comprising monomeric components of formula II as defined in claim 15, one or more binders, preferably organic binders, or precursors thereof, and optionally one or more solvents.

28. A formulation comprising one or more polymers comprising monomeric components of formula III as defined in claim 17, one or more binders, preferably organic binders, or precursors thereof, and optionally one or more solvents.

29. An organic semiconductor layer comprising one or more polymers comprising monomeric components of formula II as defined in claim 15.

30. An organic semiconductor layer comprising one or more polymers comprising monomeric components of formula III as defined in claim 17.

31. An organic semiconductor layer comprising one or more polymers comprising a formulation as defined in claim 19.

32. An organic semiconductor layer comprising one or more polymers comprising a formulation as defined in claim 20.

33. An electronic, optical or electro-optical component or device comprising polymers comprising monomeric components of formula II as defined in claim 15.

34. An electronic, optical or electro-optical component or device comprising polymers comprising monomeric components of formula III as defined in claim 17.

35. An electronic, optical or electro-optical component or device comprising a formulation as defined in claim 19.

36. An electronic, optical or electro-optical component or device comprising a formulation as defined in claim 20.

37. An electronic, optical or electro-optical component or device comprising an organic semiconductor layer as defined in claim 21.
